(19) United States
(12) Patent Application Publication
(10) Pub. No.: US 2026/0107624 A1
(43) Pub. Date: Apr. 16, 2026

(54) PHOTOELECTRIC CONVERSION ELEMENT AND PHOTODETECTOR

(71) Applicant: Sony Semiconductor Solutions Corporation, Kanagawa (JP)

(72) Inventors: Ryotaro TAKAGUCHI, Kanagawa (JP); Masahiro JOEI, Kanagawa (JP); Shintarou HIRATA, Tokyo (JP); Iwao YAGI, Kanagawa (JP); Ryosuke SUZUKI, Kanagawa (JP)

(21) Appl. No.: 19/114,682

(22) PCT Filed: Aug. 16, 2023
(86) PCT No.: PCT/JP2023/029560

§ 371 Date: Mar. 24, 2025

(30) Foreign Application Priority Data
Sep. 30, 2022 (JP) 2022-158948

(51) Int. Cl. H10K 30/81; H10K 30/60

(52) U.S. Cl. CPC H10K 30/81; H10K 30/60

(57) ABSTRACT

A first photoelectric conversion element according to an embodiment of the present disclosure includes: an electrode layer including a first electrode and a second electrode disposed side by side with each other; a third electrode disposed to be opposed to the first electrode and the second electrode; a photoelectric conversion layer provided between the electrode layer and the third electrode; an oxide semiconductor layer provided between the electrode layer and the photoelectric conversion layer; and a first insulating layer provided between the electrode layer and the oxide semiconductor layer. The first insulating layer has an opening in which an entire top surface of the first electrode is in contact with the oxide semiconductor layer without the first insulating layer being interposed therebetween.

### TECHNICAL FIELD

The present disclosure relates to a photoelectric conversion element using an organic material, for example, and a photodetector including the photoelectric conversion element.

### BACKGROUND ART

For example, PTL 1 discloses an imaging element in which a charge accumulation electrode is disposed to be spaced apart from a first electrode and opposed to a photoelectric conversion layer with an insulating layer interposed therebetween in a photoelectric conversion section in which the first electrode, the photoelectric conversion layer, and a second electrode are stacked. In this photoelectric conversion section, the first electrode is electrically coupled to the photoelectric conversion layer via an opening provided in the insulating layer.

### CITATION LIST

### Patent Literature

PTL 1: Japanese Unexamined Patent Application Publication No. 2017-157816

### SUMMARY OF THE INVENTION

Incidentally, a photodetector is required to have improved reliability.

It is desirable to provide a photoelectric conversion element and a photodetector that make it possible to improve reliability.

A first photoelectric conversion element according to an embodiment of the present disclosure includes: an electrode layer including a first electrode and a second electrode disposed side by side with each other; a third electrode disposed to be opposed to the first electrode and the second electrode; a photoelectric conversion layer provided between the electrode layer and the third electrode; an oxide semiconductor layer provided between the electrode layer and the photoelectric conversion layer; and a first insulating layer provided between the electrode layer and the oxide semiconductor layer. The first insulating layer has an opening in which an entire top surface of the first electrode is in contact with the oxide semiconductor layer without the first insulating layer being interposed therebetween.

A second photoelectric conversion element according to an embodiment of the present disclosure includes: an electrode layer including a first electrode and a second electrode disposed side by side with each other; a third electrode disposed to be opposed to the first electrode and the second electrode; a photoelectric conversion layer provided between the electrode layer and the third electrode; an oxide semiconductor layer provided between the electrode layer and the photoelectric conversion layer; a first insulating layer provided between the electrode layer and the oxide semiconductor layer, the first insulating layer having, above the first electrode, an opening that allows for electrical coupling between the first electrode and the oxide semiconductor layer; and a work function adjustment layer provided on the first electrode.

A first photodetector according to an embodiment of the present disclosure includes, for each of a plurality of pixels, one or a plurality of the first photoelectric conversion elements according to an embodiment of the present disclosure.

A second photodetector according to an embodiment of the present disclosure includes, for each of a plurality of pixels, one or a plurality of the first photoelectric conversion elements according to an embodiment of the present disclosure.

In the first photoelectric conversion element and the first photodetector according to the respective embodiments of the present disclosure, the first insulating layer is provided between the oxide semiconductor layer and the electrode layer including the first electrode and the second electrode disposed side by side with each other, and has the opening above the first electrode. In the first insulating layer, the opening is formed to allow the entire top surface of the first electrode to be in contact with the oxide semiconductor layer without the first insulating layer being interposed therebetween. This prevents formation of a parasitic transistor between the first electrode and the oxide semiconductor layer. In the second photoelectric conversion element and the second photodetector according to the respective embodiments of the present disclosure, the electrode layer including the first electrode and the second electrode disposed side by side with each other, the first insulating layer having the opening above the first electrode, the oxide semiconductor layer electrically coupled to the first electrode via the opening, the photoelectric conversion layer, and the third electrode are stacked in this order as a stacked structure. In the stacked structure, the work function adjustment layer is provided on the top surface of the first electrode. This increases a potential margin for the parasitic transistor part formed between the first electrode and the oxide semiconductor layer outside the opening.

### BRIEF DESCRIPTION OF THE DRAWINGS

FIG. 1 is a schematic cross-sectional view of an example of a configuration of a photodetection element according to a first embodiment of the present disclosure.

FIG. 2 is a schematic plan view of an example of a pixel configuration of a photodetector including the photodetection element illustrated in FIG. 1.

FIG. 3 is a schematic cross-sectional view of an example of a configuration of a photoelectric conversion section illustrated in FIG. 1.

FIG. 4A is a diagram illustrating an example of a potential of each section at the time of accumulation of electric charge.

FIG. 4B is a diagram illustrating an example of a potential of each section at the time of reading.

FIG. 5 is an equivalent circuit diagram of the photodetection element illustrated in FIG. 1.

FIG. 6 is a schematic view of an arrangement of transistors constituting a controller and a lower electrode of the photodetection element illustrated in FIG. 1.

FIG. 7 is an explanatory schematic cross-sectional view of a method of manufacturing the photodetection element illustrated in FIG. 1.

FIG. 8 is a schematic cross-sectional view of a step subsequent to FIG. 7.

FIG. 9 is a schematic cross-sectional view of a step subsequent to FIG. 8.

FIG. 10 is a schematic cross-sectional view of a step subsequent to FIG. 9.

FIG. 11 is a schematic cross-sectional view of a step subsequent to FIG. 10.

FIG. 12 is a schematic cross-sectional view of a step subsequent to FIG. 11.

FIG. 13 is a timing diagram illustrating an operation example of the photodetection element illustrated in FIG. 1.

FIG. 14 is a schematic cross-sectional view of an example of a configuration of a photoelectric conversion section as a reference example.

FIG. 15A is a diagram illustrating an example of a potential of each section at the time of accumulation of electric charge.

FIG. 15B is a diagram illustrating an example of a potential of each section at the time of reading.

FIG. 16 is a schematic cross-sectional view of an example of a configuration of a photoelectric conversion section according to Modification Example 1 of the present disclosure.

FIG. 17 is a schematic cross-sectional view of another example of the configuration of the photoelectric conversion section according to Modification Example 1 of the present disclosure.

FIG. 18 is a schematic cross-sectional view of an example of a configuration of a photoelectric conversion section according to Modification Example 2 of the present disclosure.

FIG. 19 is a schematic cross-sectional view of an example of a configuration of a photoelectric conversion section according to Modification Example 3 of the present disclosure.

FIG. 20A is an explanatory schematic cross-sectional view of a method of manufacturing the photoelectric conversion section illustrated in FIG. 19.

FIG. 20B is a schematic cross-sectional view of a step subsequent to FIG. 20A.

FIG. 20C is a schematic cross-sectional view of a step subsequent to FIG. 20B.

FIG. 20D is a schematic cross-sectional view of a step subsequent to FIG. 20C.

FIG. 21 is a schematic cross-sectional view of an example of a configuration of a photoelectric conversion section according to Modification Example 4 of the present disclosure.

FIG. 22 is a schematic plan view of an example of a pixel configuration of a photodetector including the photoelectric conversion section illustrated in FIG. 21.

FIG. 23A is an explanatory schematic cross-sectional view of a method of manufacturing the photoelectric conversion section illustrated in FIG. 21.

FIG. 23B is a schematic cross-sectional view of a step subsequent to FIG. 23A.

FIG. 23C is a schematic cross-sectional view of a step subsequent to FIG. 23B.

FIG. 23D is a schematic cross-sectional view of a step subsequent to FIG. 23C.

FIG. 23E is a schematic cross-sectional view of a step subsequent to FIG. 23D.

FIG. 23F is a schematic cross-sectional view of a step subsequent to FIG. 23E.

FIG. 24 is a schematic cross-sectional view of an example of a configuration of a photoelectric conversion section according to Modification Example 5 of the present disclosure.

FIG. 25A is an explanatory schematic cross-sectional view of a method of manufacturing the photoelectric conversion section illustrated in FIG. 24.

FIG. 25B is a schematic cross-sectional view of a step subsequent to FIG. 25A.

FIG. 25C is a schematic cross-sectional view of a step subsequent to FIG. 25B.

FIG. 25D is a schematic cross-sectional view of a step subsequent to FIG. 25C.

FIG. 26 is a schematic cross-sectional view of an example of a configuration of a photoelectric conversion section according to Modification Example 6 of the present disclosure.

FIG. 27A is an explanatory schematic cross-sectional view of a method of manufacturing the photoelectric conversion section illustrated in FIG. 26.

FIG. 27B is a schematic cross-sectional view of a step subsequent to FIG. 27A.

FIG. 27C is a schematic cross-sectional view of a step subsequent to FIG. 27B.

FIG. 27D is a schematic cross-sectional view of a step subsequent to FIG. 27C.

FIG. 28 is a schematic cross-sectional view of an example of a configuration of a photoelectric conversion section according to Modification Example 7 of the present disclosure.

FIG. 29 is a schematic cross-sectional view of an example of a configuration of a photoelectric conversion section according to Modification Example 8 of the present disclosure.

FIG. 30 is a schematic plan view of an example of a pixel configuration of a photodetector including the photoelectric conversion section illustrated in FIG. 29.

FIG. 31 is a schematic cross-sectional view of an example of a configuration of a photoelectric conversion section according to a second embodiment of the present disclosure.

FIG. 32 is a schematic plan view of an example of a pixel configuration of a photodetector including the photoelectric conversion section illustrated in FIG. 31.

FIG. 33 is a diagram illustrating an example of a potential of each section at the time of reading.

FIG. 34 is a diagram illustrating an example of an energy level of each layer on a readout electrode of the photoelectric conversion section illustrated in FIG. 31.

FIG. 35 is a schematic cross-sectional view of an example of a configuration of a photoelectric conversion section according to Modification Example 9 of the present disclosure.

FIG. 36 is a schematic cross-sectional view of an example of a configuration of a photoelectric conversion section according to Modification Example 10 of the present disclosure.

FIG. 37A is a schematic cross-sectional view of an example of a configuration of a photodetection element according to Modification Example 11 of the present disclosure.

FIG. 37B is a schematic plan view of an example of a pixel configuration of a photodetector including the photodetection element illustrated in FIG. 37A.

FIG. 38A is a schematic cross-sectional view of an example of a configuration of a photodetection element according to Modification Example 12 of the present disclosure.

FIG. 38B is a schematic plan view of an example of a pixel configuration of a photodetector including the photodetection element illustrated in FIG. 38A.

FIG. 39 is a schematic cross-sectional view of an example of a configuration of a photodetection element according to Modification Example 13 of the present disclosure.

FIG. 40 is a block diagram illustrating a configuration of a photodetector including the photodetection element illustrated in FIG. 1 and other drawings for each pixel.

FIG. 41 is a functional block diagram illustrating an example of an electronic apparatus (camera) using the photodetector illustrated in FIG. 40.

FIG. 42A is a schematic view of an example of an overall configuration of a photodetection system using the photodetector illustrated in FIG. 40.

FIG. 42B is a diagram illustrating an example of a circuit configuration of the photodetection system illustrated in FIG. 42A

FIG. 43 is a view depicting an example of a schematic configuration of an endoscopic surgery system.

FIG. 44 is a block diagram depicting an example of a functional configuration of a camera head and a camera control unit (CCU).

FIG. 45 is a block diagram depicting an example of schematic configuration of a vehicle control system.

FIG. 46 is a diagram of assistance in explaining an example of installation positions of an outside-vehicle information detecting section and an imaging section.

### MODES FOR CARRYING OUT THE INVENTION

In the following, description is given of embodiments of the present disclosure in detail with reference to the drawings. The following description is merely a specific example of the present disclosure, and the present disclosure should not be limited to the following aspects. Moreover, the present disclosure is not limited to arrangements, dimensions, dimensional ratios, and the like of each component illustrated in the drawings. It is to be noted that the description is given in the following order.
1. First Embodiment (An example of a photodetection element including a protective layer that includes a plurality of layers having different composition ratios)
   1-1. Configuration of Photodetection Element
   1-2. Method of Manufacturing Photodetection Element
   1-3. Signal Acquisition Operation of Photodetection Element
   1-4. Workings and Effects
2. Modification Examples
   2-1. Modification Example 1 (Another example of a configuration of a photoelectric conversion section)
   2-2. Modification Example 2 (Another example of the configuration of the photoelectric conversion section)
   2-3. Modification Example 3 (Another example of the configuration of the photoelectric conversion section)
   2-4. Modification Example 4 (Another example of the configuration of the photoelectric conversion section)
   2-5. Modification Example 5 (Another example of the configuration of the photoelectric conversion section)
   2-6. Modification Example 6 (Another example of the configuration of the photoelectric conversion section)
   2-7. Modification Example 7 (Another example of the configuration of the photoelectric conversion section)
   2-8. Modification Example 8 (Another example of the configuration of the photoelectric conversion section)
3. Second Embodiment (An example of a photodetection element in which a layer having an opening is added as a protective layer on an accumulation electrode)
   3-1. Configuration of Photoelectric Conversion Section
   3-2. Workings and Effects
4. Modification Examples
   4-1. Modification Example 9 (Another example of a configuration of a photoelectric conversion section)
   4-2. Modification Example 10 (Another example of the configuration of the photoelectric conversion section)
   4-3. Modification Example 11 (An example of a photodetection element that uses a color filter to disperse light)
   4-4. Modification Example 12 (Another example of the photodetection element that uses the color filter to disperse light)
   4-5. Modification Example 13 (An example of a photodetection element in which a plurality of photoelectric conversion sections is stacked)
   4-6. Other Modification Examples
5. Application Examples
6. Practical Application Examples

### 1. First Embodiment

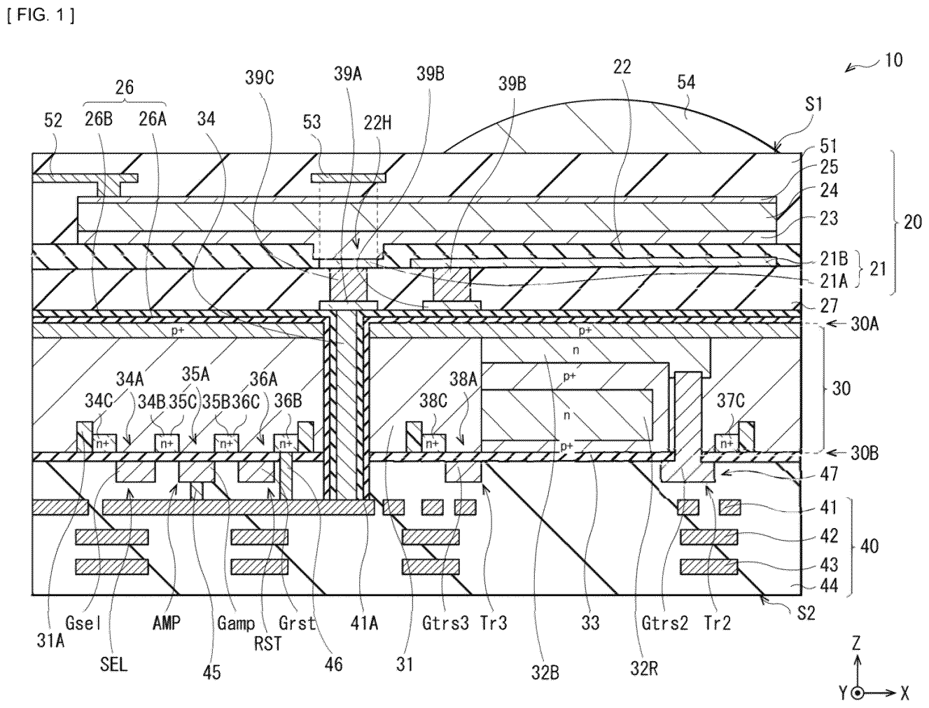

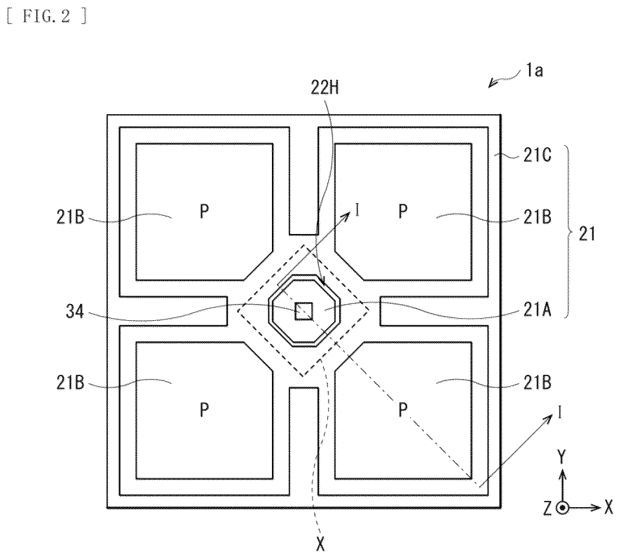

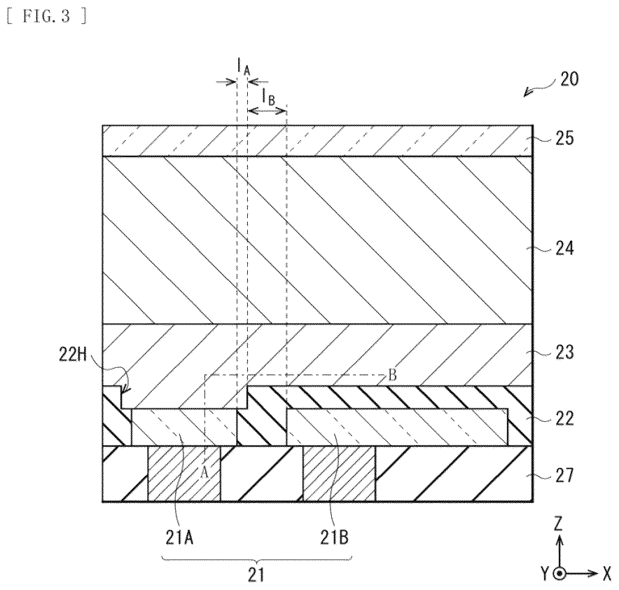

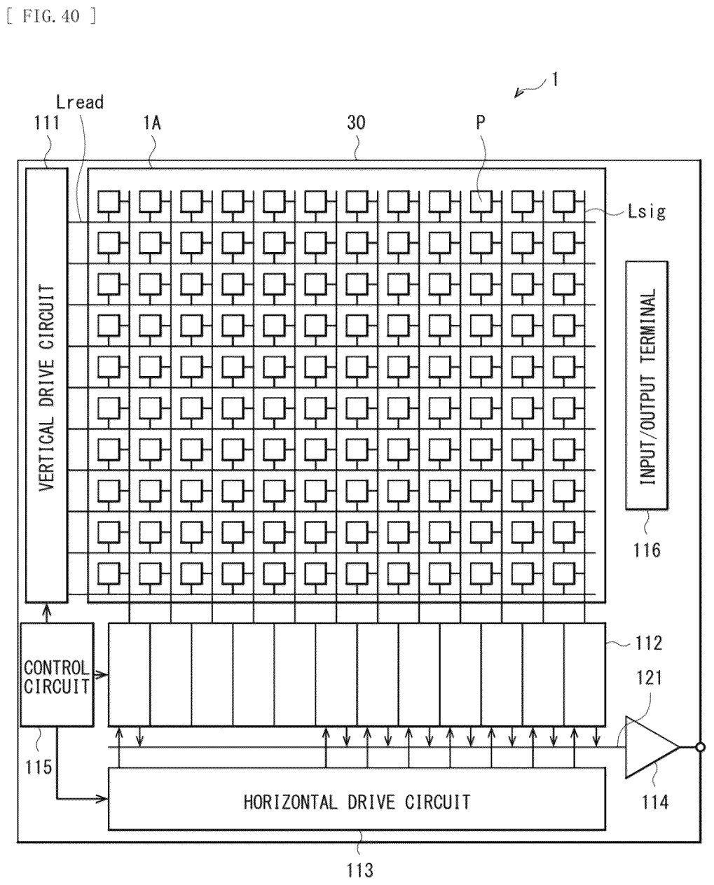

FIG. 1 schematically illustrates an example of a cross-sectional configuration of a photodetection element (a photodetection element 10) according to a first embodiment of the present disclosure. The photodetection element 10 constitutes, for example, one pixel (a unit pixel P) repeatedly arranged in array in a pixel section 1A of a photodetector (e.g., a photodetector 1; see FIG. 40) such as a CMOS (Complementary Metal Oxide Semiconductor) image sensor used for an electronic apparatus such as a digital still camera or a video camera. FIG. 2 schematically illustrates an example of a pixel configuration of the photodetector 1 including the photodetection element 10 illustrated in FIG. 1, and FIG. 1 illustrates a cross-section corresponding to a line I-I illustrated in FIG. 2. FIG. 3 schematically illustrates an example of a cross-sectional configuration of a main part (a photoelectric conversion section 20) of the photodetection element 10 illustrated in FIG. 1. In the same manner as FIG. 1, FIG. 3 illustrates a cross-section corresponding to the line I-I illustrated in FIG. 2. In the pixel section 1A, as illustrated in FIG. 2, for example, a pixel unit 1a including four unit pixels P arranged in two rows x two columns serves as a repeating unit, and is repeatedly arranged in an array including a row direction and a column direction.

The photodetection element 10 of the present embodiment is provided with a lower electrode 21 including a readout electrode 21A and an accumulation electrode 21B, an insulating layer 22, an oxide semiconductor layer 23, a photoelectric conversion layer 24, and an upper electrode 25, which are stacked in this order, in the photoelectric conversion section 20 provided on a semiconductor substrate 30. The insulating layer 22 has an opening 22H above the readout electrode 21A; at the bottom of the opening 22H, the entire top surface of the readout electrode 21A is in contact with the oxide semiconductor layer 23 without the insulating layer 22 being interposed therebetween. This readout electrode 21A corresponds to a specific example of a “first electrode” of the present disclosure, the accumulation electrode 21B corresponds to a specific example of the “first electrode” of the present disclosure, and the lower electrode 21 including the readout electrode 21A and the accumulation electrode 21B corresponds to a specific example of an “electrode layer” of the present disclosure. The upper electrode 25 corresponds to a specific example of a “third electrode” of the present disclosure. In addition, the insulating layer 22 corresponds to a specific example of a “first insulating layer” of the present disclosure, and the opening 22H corresponds to a specific example of an “opening” of the present disclosure.

### 1-1. Configuration of Photodetection Element

The photodetection element 10 is, for example, a so-called vertical spectroscopic photodetection element in which one photoelectric conversion section 20 and two photoelectric conversion regions 32B and 32R are stacked in a vertical direction. The photoelectric conversion section 20 is provided on a side of a back surface (a first surface 30A) of the semiconductor substrate 30. The photoelectric conversion regions 32B and 32R are formed to be embedded in the semiconductor substrate 30, and are stacked in a thickness direction of the semiconductor substrate 30.

The photoelectric conversion section 20 and the photoelectric conversion regions 32B and 32R selectively detect light beams in wavelength regions different from each other to perform photoelectric conversion. For example, the photoelectric conversion section 20 acquires a green (G) color signal. The photoelectric conversion regions 32B and 32R respectively acquire blue (B) and red (R) color signals depending on a difference in absorption coefficients. This enables the photodetection element 10 to acquire a plurality of types of color signals in one pixel without using color filters.

It is to be noted that, in the present embodiment, description is given of a case where electrons of electron/hole pairs (excitons) generated by photoelectric conversion are read as signal charge (in a case where an n-type semiconductor region is used as a photoelectric conversion layer). In addition, in the diagram, “+(plus)” attached to “p” and “n”indicates a higher p-type or n-type impurity concentration.

A front surface (a second surface 30B) of the semiconductor substrate 30 is provided, for example, with floating diffusions (floating diffusion layers) FD1 (a region 36B in the semiconductor substrate 30), FD2 (a region 37C in the semiconductor substrate 30), and FD3 (a region 38C in the semiconductor substrate 30), transfer transistors Tr2 and Tr3, an amplifier transistor (modulation element) AMP, a reset transistor RST, and a selection transistor SEL. The second surface 30B of the semiconductor substrate 30 is further provided with a multilayer wiring layer 40 with a gate insulating layer 33 interposed therebetween. The multilayer wiring layer 40 has, for example, a configuration in which wiring layers 41, 42, and 43 are stacked in an insulating layer 44. A peripheral part of the semiconductor substrate 30, i.e., a peripheral region 1B around the pixel section 1A is provided with a vertical drive circuit 111, a column signal processing circuit 112, a horizontal drive circuit 113, an output circuit 114, a control circuit 115, an input/output terminal 116, and the like, which are described later.

It is to be noted that the diagram illustrates a side of the first surface 30A of the semiconductor substrate 30 as a light incident side S1, and a side of the second surface 30B thereof as a wiring layer side S2.

In the photoelectric conversion section 20, the oxide semiconductor layer 23 and the photoelectric conversion layer 24 are stacked in this order from a side of the lower electrode 21 between the lower electrode 21 and the upper electrode 25 that are disposed to be opposed to each other. The photoelectric conversion layer 24 is formed by using an organic material. The photoelectric conversion layer 24 includes a p-type semiconductor and an n-type semiconductor, and has a bulk heterojunction structure therein. The bulk heterojunction structure is a p/n junction surface formed by mixing a p-type semiconductor and an n-type semiconductor.

The photoelectric conversion section 20 further includes the insulating layer 22 between the lower electrode 21 and the oxide semiconductor layer 23. The insulating layer 22 is provided, for example, across the entire surface of the pixel section 1A, and has the opening 22H on the readout electrode 21 A that constitutes the lower electrode 21. The readout electrode 21A is electrically coupled to the oxide semiconductor layer 23 via this opening 22H.

It is to be noted that FIG. 1 illustrates an example in which the oxide semiconductor layer 23, the photoelectric conversion layer 24, and the upper electrodes 25 are separately formed for each photodetection element 10, but the oxide semiconductor layer 23, the photoelectric conversion layer 24, and the upper electrode 25 may be provided, for example, as a continuous layer common to a plurality of photodetection elements 10.

For example, an insulating layer 26 and an interlayer insulating layer 27 are stacked between the first surface 30A of the semiconductor substrate 30 and the lower electrode 21. In the insulating layer 26, a layer (fixed charge layer) 26A having fixed electric charge and a dielectric layer 26B having an insulation property are stacked in this order from a side of the semiconductor substrate 30.

The photoelectric conversion regions 32B and 32R each allow light to be dispersed in the vertical direction by utilizing a difference in wavelengths of light beams to be absorbed in accordance with the light incidence depth in the semiconductor substrate 30 including a silicon substrate. The photoelectric conversion regions 32B and 32R each have a p-n junction in a predetermined region in the semiconductor substrate 30.

There is provided a through-electrode 34 between the first surface 30A and the second surface 30B of the semiconductor substrate 30. The through-electrode 34 is electrically coupled to the readout electrode 21A. The photoelectric conversion section 20 is coupled, via the through-electrode 34, to a gate Gamp of the amplifier transistor AMP and to one source/drain region 36B of the reset transistor RST (a reset transistor Tr1rst) also serving as the floating diffusion FD1. This enables the photodetection element 10 to favorably transfer charge carriers (electrons here) generated by the photoelectric conversion section 20 provided on the side of the first surface 30A of the semiconductor substrate 30 to the side of the second surface 30B of the semiconductor substrate 30 via the through-electrode 34 and thus to enhance the characteristics.

The lower end of the through-electrode 34 is coupled to wiring (a coupling section 41A) in the wiring layer 41, and the coupling section 41A and the gate Gamp of the amplifier transistor AMP are coupled to each other via a lower first contact 45. The coupling section 41A and the floating diffusion FD1 (region 36B) are coupled to each other, for example, via a lower second contact 46. The upper end of the through-electrode 34 is coupled to the readout electrode 21A, for example, via a pad section 39A and an upper first contact 39C.

A protective layer 51 is provided above the photoelectric conversion section 20. In the protective layer 51, for example, there are provided wiring 52 and a light-blocking film 53. The wiring 52 electrically couples the upper electrode 25 and a peripheral circuit part 130 to each other around the pixel section 1A. An optical member such as an on-chip lens 54 or a planarization layer (unillustrated) is further disposed above the protective layer 51.

In the photodetection element 10 of the present embodiment, light having entered the photoelectric conversion section 20 from the light incident side S1 is absorbed by the photoelectric conversion layer 24. Excitons generated thereby move to an interface between an electron donor and an electron acceptor constituting the photoelectric conversion layer 24 to undergo exciton separation. In other words, the excitons are dissociated into electrons and holes. Charge carriers (electrons and holes) generated here are transported to different electrodes by diffusion due to a charge carrier concentration difference or by an internal electric field caused by a work function difference between an anode (e.g., the upper electrode 25) and a cathode (e.g., the lower electrode 21). The transported charge carriers are detected as a photocurrent. In addition, application of a potential between the lower electrode 21 and the upper electrode 25 also makes it possible to control transport directions of electrons and holes.

Hereinafter, description is given in detail of configurations, materials, and the like of each of the sections.

The photoelectric conversion section 20 is an organic photoelectric conversion element that absorbs, for example, green light corresponding to a portion or the whole of a selective wavelength region (e.g., 450 nm or more and 650 nm or less) to generate excitons.

The lower electrode 21 includes, for example, the readout electrode 21A and the accumulation electrode 21B disposed side by side with each other on the interlayer insulating layer 27. The readout electrode 21A is provided to transfer charge carriers generated in the photoelectric conversion layer 24 to the floating diffusion FD1, and is provided one by one for each pixel unit 1a including four pixels that are arranged in two rows×two columns, for example.

The readout electrode 21A is coupled to the floating diffusion FD1, for example, via the upper first contact 39C, the pad section 39A, the through-electrode 34, the coupling section 41A, and the lower second contact 46.

The accumulation electrode 21B is provided to accumulate, in the oxide semiconductor layer 23, electrons, for example, among the charge carriers generated in the photoelectric conversion layer 24, as signal charge. The accumulation electrode 21B is provided for each of the pixels. The accumulation electrode 21B is provided for each of the unit pixels P, in a region that is opposed to light receiving surfaces of the photoelectric conversion regions 32B and 32R formed in the semiconductor substrate 30 and that covers these light receiving surfaces. It is preferable that the accumulation electrode 21B be larger than the readout electrode 21A. This makes it possible to accumulate more charge carriers.

The lower electrode 21 may further include a pixel separation electrode 21C that is opposed to the oxide semiconductor layer 23 with the insulating layer 22 interposed therebetween, in the same manner as the accumulation electrode 21B. The pixel separation electrode 21C is provided to prevent capacitive coupling between pixel units 1a adjacent to each other. The pixel separation electrode 21C is provided around the pixel unit 1a including four pixels arranged in two rows×two columns, for example, and receives application of a fixed potential. The pixel separation electrode 21C further extends, in the pixel unit 1a, between pixels adjacent to each other in the row direction (a Z-axis direction) and the column direction (an X-axis direction).

The lower electrode 21 includes an electrically-conductive film having light transmissivity. The lower electrode 21 is configured by, for example, ITO (indium tin oxide). In addition to ITO, a tin oxide (SnO₂)-based material doped with a dopant or a zinc oxide-based material in which zinc oxide (ZnO) is doped with a dopant may be used as a constituent material of the lower electrode 21. Examples of the zinc oxide-based material include aluminum zinc oxide (AZO) doped with aluminum (Al) as a dopant, gallium zinc oxide (GZO) doped with gallium (Ga), and indium zinc oxide (IZO) doped with indium (In). In addition, IGZO, ITZO, CuI, InSbO₄, ZnMgO, CuInO₂, MgIN₂O₄, CdO, ZnSnO₃, or the like may also be used in addition thereto.

The insulating layer 22 is provided to electrically separate the accumulation electrode 21B and the oxide semiconductor layer 23 from each other. The insulating layer 22 is provided, for example, above the interlayer insulating layer 27 to cover the lower electrode 21. The insulating layer 22 is provided with the opening 22H on the readout electrode 21A of the lower electrode 21, and the readout electrode 21A and the oxide semiconductor layer 23 are electrically coupled to each other via this opening 22H.

As described above, in the opening 22H, the entire top surface of the readout electrode 21A is in contact with the oxide semiconductor layer 23 without the insulating layer 22 being interposed therebetween. In other words, as for an area, the bottom of the opening 22H has an area equal to or more than an area of the top surface of the readout electrode 21A. That is, an end of the bottom of the opening 22H coincides with an end of the top surface of the readout electrode 21A, or is formed outside the end of the top surface of the readout electrode 21A. However, it is preferable that the end of the bottom of the opening 22H be formed inside a dotted line region illustrated in FIG. 2. The dotted line region is a region of a dotted line that traces positions of equal distances between the end of the readout electrode 21A and four accumulation electrodes 21B arranged at four corners about the readout electrode 21A in the pixel unit 1a including four pixels arranged in two rows×two columns. In other words, it is preferable that a minimum distance I_{A} between the end of the bottom of the opening 22H and the end of the top surface of the readout electrode 21A be smaller than a minimum distance 1B between the end of the bottom of the opening 22H and an end of a top surface of the accumulation electrode 21B. In addition, as illustrated in FIG. 2, the end of the bottom of the opening 22H is not above the pixel separation electrode 21C; the pixel separation electrode 21C and the oxide semiconductor layer 23 are not in contact with each other in the opening 22H.

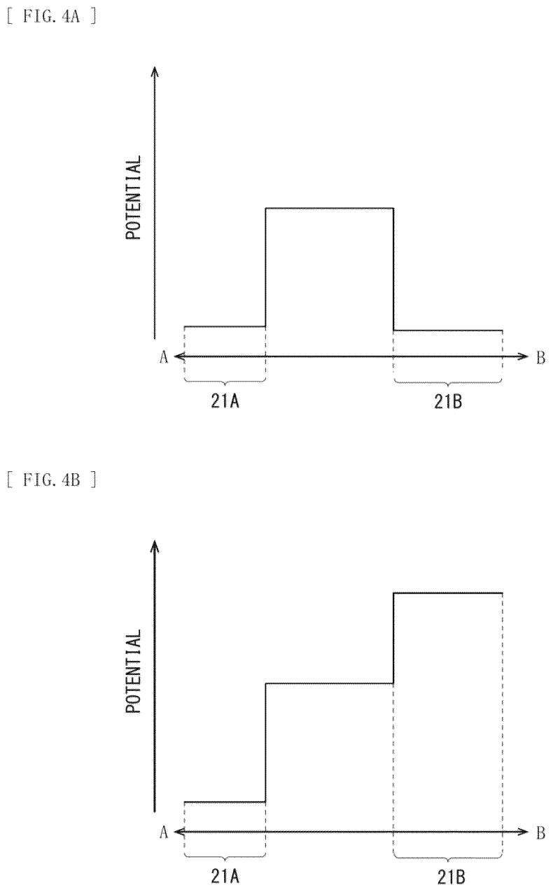

FIG. 4A illustrates an example of a potential between A and B illustrated in FIG. 3 at the time of accumulation of electric charge. FIG. 4B illustrates an example of a potential between A and B illustrated in FIG. 3 at the time of reading. As described later in detail, in the photodetection element 10, a potential equal to or more than a potential to be applied to the readout electrode 21A is applied to the accumulation electrode 21B at the time of accumulation of electric charge. At that time, as illustrated in FIG. 4A, an area between the readout electrode 21A and the accumulation electrode 21B becomes a barrier to cause charge carriers (here, electrons) to be accumulated in a region of the oxide semiconductor layer 23 opposed to the accumulation electrode 21B. At the time of reading, a potential larger than that of the accumulation electrode 21B is applied to the readout electrode 21A to thereby allow potentials of respective sections between A and B to have a stair-like shape, as illustrated in FIG. 4B. This allows the charge carriers accumulated in the region of the oxide semiconductor layer 23 opposed to the accumulation electrode 21B to be transferred toward the readout electrode 21A.

When the area of the bottom of the opening 22H is widened too much, e.g., when the end of the bottom of the opening 22H is formed outside the dotted line region illustrated in FIG. 2, it becomes difficult to control a potential between the readout electrode 21A and the accumulation electrode 21B. For example, at the time of accumulation of electric charge, a width of the barrier between the readout electrode 21A and the accumulation electrode 21B may possibly be narrowed, causing the potential between the readout electrode 21A and the accumulation electrode 21B to be dragged by a potential of the accumulation electrode 21B, thus reducing an amount of charge carriers that are able to be built up. In addition, at the time of reading, the potential between the readout electrode 21A and the accumulation electrode 21B may possibly be dragged too low by the potential of the readout electrode 21A, thus causing the charge carriers accumulated in the region of the oxide semiconductor layer 23 not to be fully transferred to the readout electrode 21A. It is therefore preferable that the end of the bottom of the opening 22H be formed inside the dotted line region illustrated in FIG. 2.

It is to be noted that FIGS. 1 and 3 illustrate an example in which a sidewall of the opening 22H is formed vertically on the first surface 30A (an X-Y plane) of the semiconductor substrate 30; however, this is not limitative. For example, the sidewall of the opening 22H may be inclined to allow a cross-sectional shape of the opening 22H to be wider toward the light incident side S1. In addition, FIG. 2 illustrates an example in which the opening 21H and the readout electrode 21A have similar planar shapes; however, this is not limitative. That is, the planar shape of the opening 21H may be a planar shape substantially the same as that of the readout electrode 21A, or may be a different planar shape such as a circular shape, for example.

The insulating layer 22 is configured by, for example, a monolayer film including one of silicon oxide (SiOₓ), silicon nitride (SiNₓ), silicon oxynitride (SiON), or the like, or a stacked film including two or more thereof. In addition to the above, for example, hafnium oxide (HfOₓ) or aluminum oxide (AlOₓ) may be used for the insulating layer 22. The insulating layer 22 has a thickness of 20 nm to 500 nm, for example.

The oxide semiconductor layer 23 is provided to accumulate charge carriers generated by the photoelectric conversion layer 24. The oxide semiconductor layer 23 may be formed using, for example, an oxide semiconductor material including at least one element of indium (In), gallium (Ga), silicon (Si), zinc (Zn), aluminum (Al), or tin (Sn). In the present embodiment, electrons of the charge carriers generated by the photoelectric conversion layer 24 are used as signal charge. This enables formation of the oxide semiconductor layer 23 by using an n-type oxide semiconductor material. Specific examples of the constituent material of the oxide semiconductor layer 23 include IGZO, Ga₂O₃, GZO, IZO, ITO, InGaAIO, and InGaSiO. The oxide semiconductor layer 23 has a thickness of 10 nm to 300 nm, for example.

The photoelectric conversion layer 24 converts optical energy into electric energy. The photoelectric conversion layer 24 includes, for example, two or more types of organic materials (a p-type semiconductor material or an n-type semiconductor material) that each function as a p-type semiconductor or an n-type semiconductor. The photoelectric conversion layer 24 has, therein, a junction surface (p/n junction surface) between the p-type semiconductor material and the n-type semiconductor material. The p-type semiconductor relatively functions as an electron donor (donor), and the n-type semiconductor relatively functions as an electron acceptor (acceptor). The photoelectric conversion layer 24 provides a field where excitons generated in absorbing light are separated into electrons and holes. Specifically, excitons are separated into electrons and holes at the interface (p/n junction surface) between the electron donor and the electron acceptor.

The photoelectric conversion layer 24 may include an organic material, i.e., a so-called coloring material, in addition to the p-type semiconductor material and the n-type semiconductor material. The organic material, i.e., the coloring material photoelectrically converts light in a predetermined wavelength region while transmitting light in another wavelength region. In a case where the photoelectric conversion layer 24 is formed by using the three types of organic materials of a p-type semiconductor material, an n-type semiconductor material, and a coloring material, it is preferable that the p-type semiconductor material and the n-type semiconductor material be materials each having light transmissivity in a visible region (e.g., 450 nm to 800 nm). The photoelectric conversion layer 24 has a thickness of 50 nm to 500 nm, for example.

Examples of organic materials constituting the photoelectric conversion layer 24 include a quinacridone derivative, a naphthalene derivative, an anthracene derivative, a phenanthrene derivative, a tetracene derivative, a pyrene derivative, a perylene derivative, and a fluoranthene derivative. The photoelectric conversion layer 24 includes two or more types of the above-described organic materials in combination. The above-described organic materials function as a p-type semiconductor or an n-type semiconductor depending on the combination.

It is to be noted that the organic materials constituting the photoelectric conversion layer 24 are not limited in particular. It is possible to use, for example, a polymer such as phenylenevinylene, fluorene, carbazole, indole, pyrene, pyrrole, picoline, thiophene, acetylene, diacetylene, or the like, or a derivative thereof, in addition to the above-described organic materials. Alternatively, it is possible to use a metal complex dye, a cyanine-based dye, a merocyanine-based dye, a phenylxanthene-based dye, a triphenylmethane-based dye, a rhodacyanine-based dye, a xanthene-based dye, a macrocyclic azaannulene-based dye, an azulene-based dye, a naphthoquinone-based dye, an anthraquinone-based dye, a chain compound in which a fused polycyclic aromatic group such as pyrene, an aromatic ring, or a heterocyclic compound is fused, a cyanine-like dye bonded by two nitrogen-containing hetero rings including quinoline, benzothiazole, benzoxazole, and the like that have a squarylium group and a croconic methine group as a bonded chain or by a squarylium group and a croconic methine group, or the like. It is to be noted that examples of the metal complex dye include a dithiol metal complex-based dye, a metallophthalocyanine dye, a metalloporphyrine dye, and a ruthenium complex dye. A ruthenium complex dye is preferable in particular among them, but the metal complex dye is not limited thereto.

The upper electrode 25 is configured by an electrically-conductive film having light transmissivity in the same manner as the lower electrode 21. The upper electrode 25 is configured by, for example, ITO (indium tin oxide). In addition to this ITO, a tin oxide (SnO₂)-based material doped with a dopant or a zinc oxide-based material in which zinc oxide (ZnO) is doped with a dopant may be used as a constituent material of the upper electrode 25. Examples of the zinc oxide-based material include aluminum zinc oxide (AZO) doped with aluminum (Al) as a dopant, gallium zinc oxide (GZO) doped with gallium (Ga), and indium zinc oxide (IZO) doped with indium (In). In addition, IGZO, ITZO, Cul, InSbO₄, ZnMgO, CuInO₂, MgIN₂O₄, CdO, ZnSnO₃, or the like may also be used in addition thereto. The upper electrodes 25 may be separated for each of the pixels, or the upper electrode 25 may be formed as an electrode common to the pixels. The upper electrode 25 has a thickness of 10 nm to 200 nm, for example.

It is to be noted that the photoelectric conversion section 20 may be provided with other layers between the lower electrode 21 and the photoelectric conversion layer 24 (e.g., between the oxide semiconductor layer 23 and the photoelectric conversion layer 24) and between the photoelectric conversion layer 24 and the upper electrode 25. For example, in the photoelectric conversion section 20, a buffer layer also serving as an electron blocking film, the photoelectric conversion layer 24, a buffer layer also serving as a hole blocking film, a work function adjustment layer, and the like may be stacked in order from the side of the lower electrode 21. In addition, the photoelectric conversion layer 24 may have a pin bulk heterostructure in which, for example, a p-type blocking layer, a layer (i-layer) including a p-type semiconductor and an n-type semiconductor, and an n-type blocking layer are stacked.

The insulating layer 26 covers the first surface 30A of the semiconductor substrate 30 and reduces the interface state with the semiconductor substrate 30. In addition, the insulating layer 26 is provided to suppress generation of a dark current from the interface with the semiconductor substrate 30. In addition, the insulating layer 26 extends from the first surface 30A of the semiconductor substrate 30 to a side surface of the opening 34H (see FIG. 1) in which the through-electrode 34 is formed. The through-electrode 34 penetrates the semiconductor substrate 30. The insulating layer 26 has, for example, a stacked structure of the fixed charge layer 26A and the dielectric layer 26B.

The fixed charge layer 26A may be a film having positive fixed electric charge, or may be a film having negative fixed electric charge. Examples of the constituent material of the fixed charge layer 26A include an electrically-conductive material or a semiconductor material having a wider band gap than that of the semiconductor substrate 30. This makes it possible to suppress generation of a dark current at the interface of the semiconductor substrate 30. Examples of the constituent material of the fixed charge layer 26A include hafnium oxide (HfOₓ), aluminum oxide (AlOₓ), zirconium oxide (ZrOₓ), tantalum oxide (TaOₓ), titanium oxide (TiOₓ), lanthanum oxide (LaOₓ), praseodymium oxide (PrOₓ), cerium oxide (CeOₓ), neodymium oxide (NdOₓ), promethium oxide (PmOₓ), samarium oxide (SmOₓ), europium oxide (EuOₓ), gadolinium oxide (GdOₓ), terbium oxide (TbOₓ), dysprosium oxide (DyOₓ), holmium oxide (HoOₓ), thulium oxide (TmOₓ), ytterbium oxide (YbOₓ), lutetium oxide (LuOₓ), yttrium oxide (YOₓ), hafnium nitride (HfNₓ), aluminum nitride (AlNₓ), hafnium oxynitride (HfOₓN_{y}), and aluminum oxynitride (AlOₓN_{y}).

The dielectric layer 26B is provided to prevent light reflection caused by a refractive index difference between the semiconductor substrate 30 and the interlayer insulating layer 27. As a constituent material of the dielectric layer 26B, it is preferable to adopt a material having a refractive index between a refractive index of the semiconductor substrate 30 and a refractive index of the interlayer insulating layer 27. Examples of the constituent material of the dielectric layer 26B include silicon oxide, TEOS, silicon nitride, silicon oxynitride (SiON), and the like.

The interlayer insulating layer 27 is configured by, for example, a monolayer film including one of silicon oxide, silicon nitride, silicon oxynitride, or the like, or a stacked film including two or more thereof.

The semiconductor substrate 30 is configured by, for example, an n-type silicon (Si) substrate, and includes a p-well 31 in a predetermined region.

The photoelectric conversion regions 32B and 32R are each configured by a photodiode (PD) having a p-n junction in a predetermined region in the semiconductor substrate 30, and enable light to be dispersed in the vertical direction by utilizing a difference in wavelengths of light beams to be absorbed depending on incidence depth of light in the Si substrate. The photoelectric conversion region 32B, for example, selectively detects blue light and accumulates signal charge corresponding to blue; the photoelectric conversion region 32B is provided at a depth at which the blue light is able to be efficiently subjected to photoelectric conversion. The photoelectric conversion region 32R, for example, selectively detects red light and accumulates signal charge corresponding to red; the photoelectric conversion region 32R is provided at a depth at which the red light is able to be efficiently subjected to photoelectric conversion. It is to be noted that blue (B) is a color corresponding to a wavelength region of 450 nm to 495 nm, for example, and red (R) is a color corresponding to a wavelength region of 620 nm to 750 nm, for example. It is sufficient for each of the photoelectric conversion regions 32B and 32R to be able to detect light in a portion or the whole of each wavelength region.

The photoelectric conversion region 32B includes, for example, a p+ region serving as a hole accumulation layer and an n region serving as an electron accumulation layer. The photoelectric conversion region 32R includes, for example, a p+ region serving as a hole accumulation layer and an n region serving as an electron accumulation layer (having a p-n-p stacked structure). The n region of the photoelectric conversion region 32B is coupled to the vertical transfer transistor Tr2. The p+ region of the photoelectric conversion region 32B bends along the transfer transistor Tr2, and is linked to the p+ region of the photoelectric conversion region 32R.

The gate insulating layer 33 is configured by, for example, a monolayer film including one of silicon oxide, silicon nitride, silicon oxynitride, or the like, or a stacked film including two or more thereof.

The through-electrode 34 is provided between the first surface 30A and the second surface 30B of the semiconductor substrate 30. The through-electrode 34 has a function as a connector for the photoelectric conversion section 20 and the gate Gamp of the amplifier transistor AMP as well as the floating diffusion FD1, and serves as a transmission path for the charge carriers generated by the photoelectric conversion section 20. A reset gate Grst of the reset transistor RST is disposed next to the floating diffusion FD1 (one source/drain region 36B of the reset transistor RST). This enables the reset transistor RST to reset the charge carriers accumulated in the floating diffusion FD1.

The pad sections 39A and 39B, the upper first contact 39C, an upper second contact 39D, the lower first contact 45, the lower second contact 46, and the wiring 52 may be formed using a doped silicon material such as PDAS (Phosphorus Doped Amorphous Silicon), or a metal material such as aluminum (Al), tungsten (W), titanium (Ti), cobalt (Co), hafnium (Hf), or tantalum (Ta).

The protective layer 51 and the on-chip lens 54 are configured by a material having light transmissivity, and are configured by, for example, a monolayer film including one of silicon oxide, silicon nitride, silicon oxynitride, or the like, or a stacked film including two or more thereof. The protective layer 51 has a thickness of 100 nm to 30000 nm, for example.

For example, the light-blocking film 53 is provided, in the protective layer 51 together with the wiring 52, to cover a region of the readout electrode 21A in direct contact with the oxide semiconductor layer 23 without covering at least the accumulation electrode 21B. The light-blocking film 53 may be formed using, for example, tungsten (W), aluminum (Al), an alloy of Al and copper (Cu), or the like.

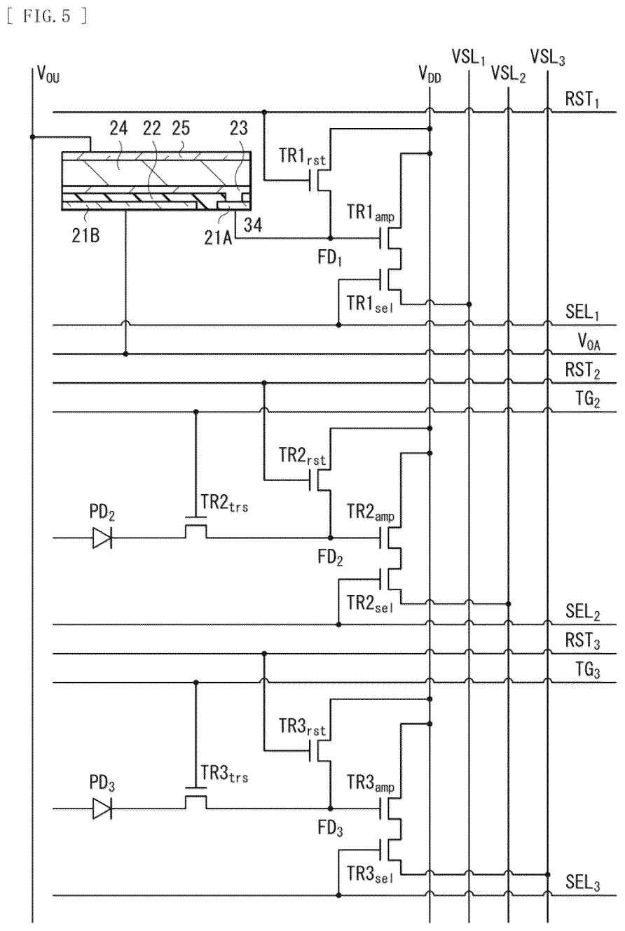

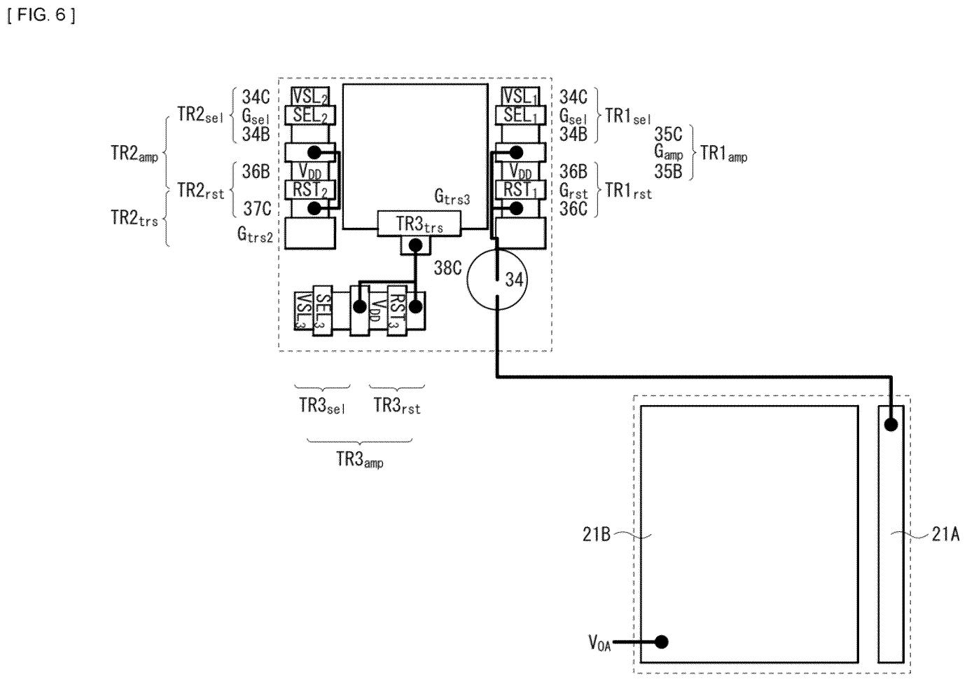

FIG. 5 is an equivalent circuit diagram of the photodetection element 10 illustrated in FIG. 1. FIG. 6 schematically illustrates an arrangement of transistors constituting a controller and the lower electrode 21 of the photodetection element 10 illustrated in FIG. 1.

The reset transistor RST (a reset transistor TR1rst) is provided to reset charge carriers transferred from the photoelectric conversion section 20 to the floating diffusion FD1, and is configured by a MOS transistor, for example. Specifically, the reset transistor TR1rst is configured by the reset gate Grst, a channel formation region 36A, and source/drain regions 36B and 36C. The reset gate Grst is coupled to a reset line RST1. The one source/drain region 36B of the reset transistor TR1rst also serves as the floating diffusion FD1. The other source/drain region 36C constituting the reset transistor TR1rst is coupled to a power supply line VDD.

The amplifier transistor AMP (an amplifier transistor TR1amp) is a modulation element that modulates, to a voltage, the amount of electric charge generated by the photoelectric conversion section 20, and is configured by a MOS transistor, for example. Specifically, the amplifier transistor AMP is configured by the gate Gamp, a channel formation region 35A, and source/drain regions 35B and 35C. The gate Gamp is coupled to the readout electrode 21A and the one source/drain region 36B (floating diffusion FD1) of the reset transistor TR1rst via the lower first contact 45, the coupling section 41A, the lower second contact 46, the through-electrode 34, and the like. In addition, the one source/drain region 35B shares a region with the other source/drain region 36C constituting the reset transistor TR1rst, and is coupled to the power supply line VDD.

The selection transistor SEL (a selection transistor TR1sel) is configured by a gate Gsel, a channel formation region 34A, and source/drain regions 34B and 34C. The gate Gsel is coupled to a selection line SEL1. The one source/drain region 34B shares a region with the other source/drain region 35C constituting the amplifier transistor AMP, and the other source/drain region 34C is coupled to a signal line (data output line) VSL1.

A transfer transistor TR2 (a transfer transistor TR2trs) is provided to transfer, to the floating diffusion FD2, signal charge corresponding to blue that has been generated and accumulated in the photoelectric conversion region 32B. The photoelectric conversion region 32B is formed at a deep position from the second surface 30B of the semiconductor substrate 30, and it is thus preferable that the transfer transistor TR2trs of the photoelectric conversion region 32B be configured by a vertical transistor. The transfer transistor TR2trs is coupled to a transfer gate line TG2. The floating diffusion FD2 is provided in the region 37C near a gate Gtrs2 of the transfer transistor TR2trs. The charge carriers accumulated in the photoelectric conversion region 32B are read to the floating diffusion FD2 via a transfer channel formed along the gate Gtrs2.

The transfer transistor TR3 (a transfer transistor TR3trs) is provided to transfer, to the floating diffusion FD3, signal charge corresponding to red that has been generated and accumulated in the photoelectric conversion region 32R. The transfer transistor TR3 (transfer transistor TR3trs) is configured by, for example, a MOS transistor. The transfer transistor TR3trs is coupled to a transfer gate line TG3. The floating diffusion FD3 is provided in a region 38C near a gate Gtrs3 of the transfer transistor TR3trs. The charge carriers accumulated in the photoelectric conversion region 32R are read to the floating diffusion FD3 via a transfer channel formed along the gate Gtrs3.

The side of the second surface 30B of the semiconductor substrate 30 is further provided with a reset transistor TR2rst, an amplifier transistor TR2amp, and a selection transistor TR2sel constituting a controller of the photoelectric conversion region 32B. Further, there are provided a reset transistor TR3rst, an amplifier transistor TR3amp, and a selection transistor TR3sel constituting a controller of the photoelectric conversion region 32R.

The reset transistor TR2rst is configured by a gate, a channel formation region, and source/drain regions. The gate of the reset transistor TR2rst is coupled to a reset line RST2, and the one source/drain region of the reset transistor TR2rst is coupled to the power supply line VDD. The other source/drain region of the reset transistor TR2rst also serves as the floating diffusion FD2.

The amplifier transistor TR2amp is configured by a gate, a channel formation region, and source/drain regions. The gate is coupled to the other source/drain region (floating diffusion FD2) of the reset transistor TR2rst. The one source/drain region constituting the amplifier transistor TR2amp shares a region with the one source/drain region constituting the reset transistor TR2rst, and is coupled to the power supply line VDD.

The selection transistor TR2sel is configured by a gate, a channel formation region, and source/drain regions. The gate is coupled to a selection line SEL2. The one source/drain region constituting the selection transistor TR2sel shares a region with the other source/drain region constituting the amplifier transistor TR2amp. The other source/drain region constituting the selection transistor TR2sel is coupled to a signal line (data output line) VSL2.

The reset transistor TR3rst is configured by a gate, a channel formation region, and source/drain regions. The gate of the reset transistor TR3rst is coupled to a reset line RST3, and the one source/drain region constituting the reset transistor TR3rst is coupled to the power supply line VDD. The other source/drain region constituting the reset transistor TR3rst also serves as the floating diffusion FD3.

The amplifier transistor TR3amp is configured by a gate, a channel formation region, and source/drain regions. The gate is coupled to the other source/drain region (floating diffusion FD3) constituting the reset transistor TR3rst. The one source/drain region constituting the amplifier transistor TR3amp shares a region with the one source/drain region constituting the reset transistor TR3rst, and is coupled to the power supply line VDD.

The selection transistor TR3sel is configured by a gate, a channel formation region, and source/drain regions. The gate is coupled to a selection line SEL3. The one source/drain region constituting the selection transistor TR3sel shares a region with the other source/drain region constituting the amplifier transistor TR3amp. The other source/drain region constituting the selection transistor TR3sel is coupled to a signal line (data output line) VSL3.

The reset lines RST1, RST2, and RST3, the selection lines SEL1, SEL2, and SEL3, and the transfer gate lines TG2 and TG3 are each coupled to a vertical drive circuit constituting a drive circuit. The signal lines (data output lines) VSL1, VSL2, and VSL3 are coupled to the column signal processing circuit 112 constituting the drive circuit.

It is to be noted that, in the photodetection element 10, the protective layer 51 and an optical black (OPB) layer are formed on the photoelectric conversion section 20 near a peripheral region provided around the pixel section 1A. The protective layer 51 and the OPB layer cover a side surface of the photoelectric conversion section 20, for example, and extend to the peripheral region.

### 1-2. Method of Manufacturing Photodetection Element

The photodetection element 10 according to the present embodiment may be manufactured, for example, as follows.

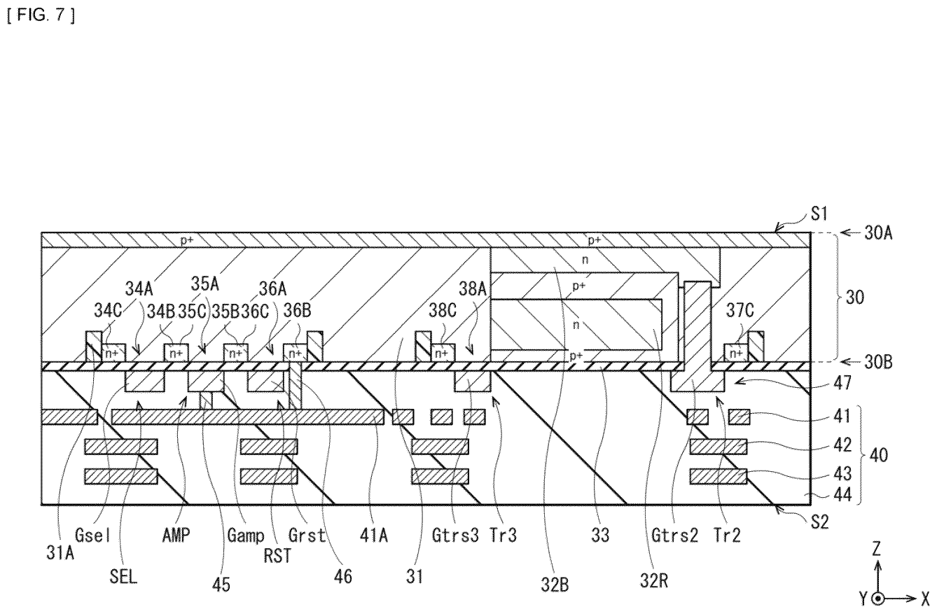

FIGS. 7 to 12 illustrate a method of manufacturing the photodetection element 10 in the order of steps. First, as illustrated in FIG. 7, for example, the p-well 31 is formed in the semiconductor substrate 30, and the photoelectric conversion regions 32B and 32R of an n type, for example, are formed in this p-well 31. A p+ region is formed near the first surface 30A of the semiconductor substrate 30.

As also illustrated in FIG. 7, for example, n+ regions that serve as the floating diffusions FD1 to FD3 are formed on the second surface 30B of the semiconductor substrate 30, and the gate insulating layer 33 and a gate wiring layer 47 are then formed. The gate wiring layer 47 includes the respective gates of the transfer transistor Tr2, the transfer transistor Tr3, the selection transistor SEL, the amplifier transistor AMP, and the reset transistor RST. This forms the transfer transistor Tr2, the transfer transistor Tr3, the selection transistor SEL, the amplifier transistor AMP, and the reset transistor RST. Further, the multilayer wiring layer 40 is formed on the second surface 30B of the semiconductor substrate 30. The multilayer wiring layer 40 includes the wiring layers 41 to 43 and the insulating layer 44. The wiring layers 41 to 43 include the lower first contact 45, the lower second contact 46, and the coupling section 41A.

As the base of the semiconductor substrate 30, for example, an SOI (Silicon on Insulator) substrate is used in which the semiconductor substrate 30, an embedded oxide film (unillustrated), and a holding substrate (unillustrated) are stacked. Although not illustrated in FIG. 7, the embedded oxide film and the holding substrate are joined to the first surface 30A of the semiconductor substrate 30. After ion implantation, annealing treatment is performed.

Next, a support substrate (unillustrated), another semiconductor base, or the like is joined onto the multilayer wiring layer 40 provided on the side of the second surface 30B of the semiconductor substrate 30, and the substrate is turned upside down. Subsequently, the semiconductor substrate 30 is separated from the embedded oxide film and the holding substrate of the SOI substrate to expose the first surface 30A of the semiconductor substrate 30. The above-described steps may be performed with a technique used in a normal CMOS process such as ion implantation and CVD (Chemical Vapor Deposition) methods.

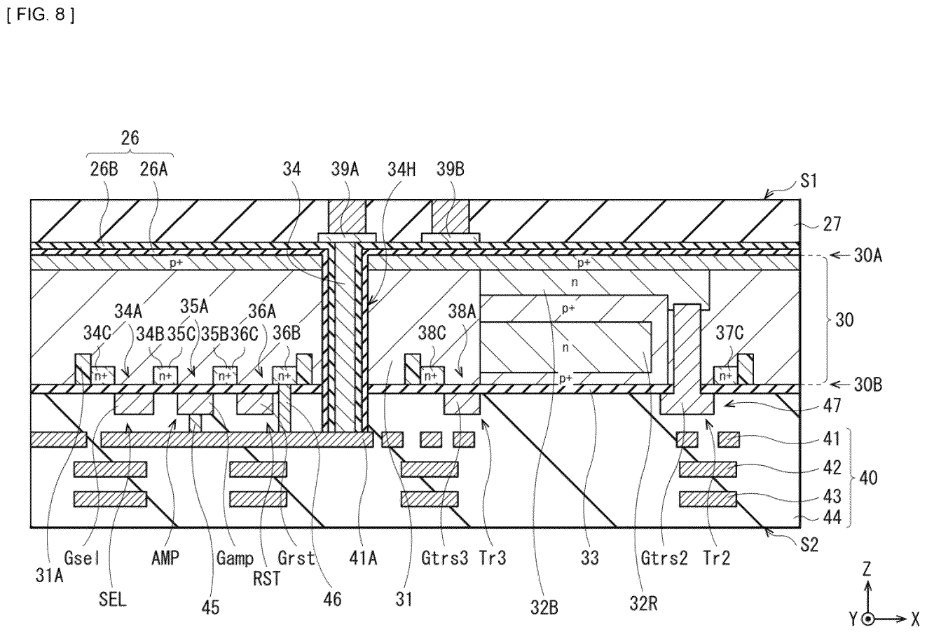

Next, as illustrated in FIG. 8, the semiconductor substrate 30 is worked from the side of the first surface 30A, for example, by dry etching to form, for example, an annular opening 34H. As for a depth, the opening 34H penetrates from the first surface 30A to the second surface 30B of the semiconductor substrate 30, and reaches, for example, the coupling section 41A, as illustrated in FIG. 8.

Subsequently, for example, the fixed charge layer 26A and the dielectric layer 26B are formed in order on the first surface 30A of the semiconductor substrate 30 and on a side surface of the opening 34H. The fixed charge layer 26A may be formed by forming a hafnium oxide film or an aluminum oxide film using an atomic layer deposition method (ALD method), for example. The dielectric layer 26B may be formed by forming a silicon oxide film using a plasma CVD method, for example. Next, for example, the pad sections 39A and 39B are formed at predetermined positions on the dielectric layer 26B. In the pad sections 39A and 39B, a barrier metal including a stacked film (Ti/TiN film) of titanium and titanium nitride and a tungsten film are stacked. This enables the pad sections 39A and 39B to be used as light-blocking films. Thereafter, the interlayer insulating layer 27 is formed on the dielectric layer 26B and the pad sections 39A and 39B, and a surface of the interlayer insulating layer 27 is planarized using a CMP (Chemical Mechanical Polishing) method.

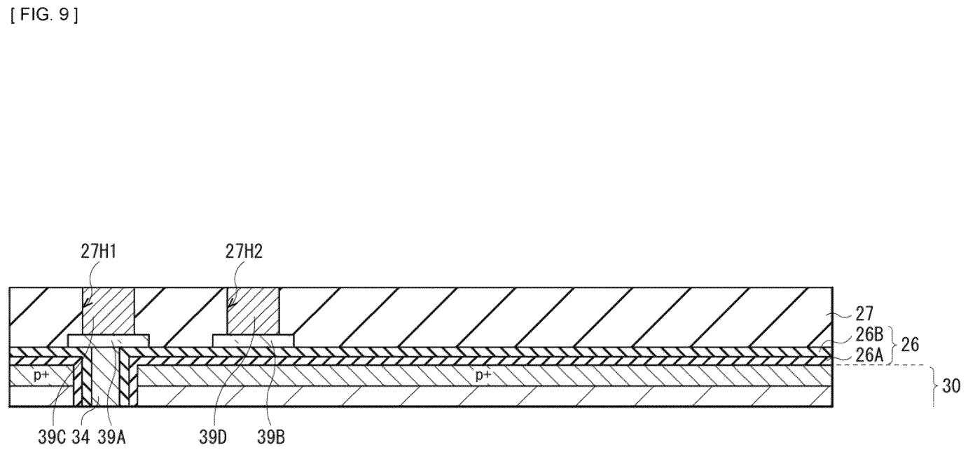

Subsequently, as illustrated in FIG. 9, openings 27H1 and 27H2 are formed, respectively, on the pad sections 39A and 39B, and then an electrically-conductive material such as Al, for example, is embedded in the openings 27H1 and 27H2 to form the upper first contact 39C and the upper second contact 39D.

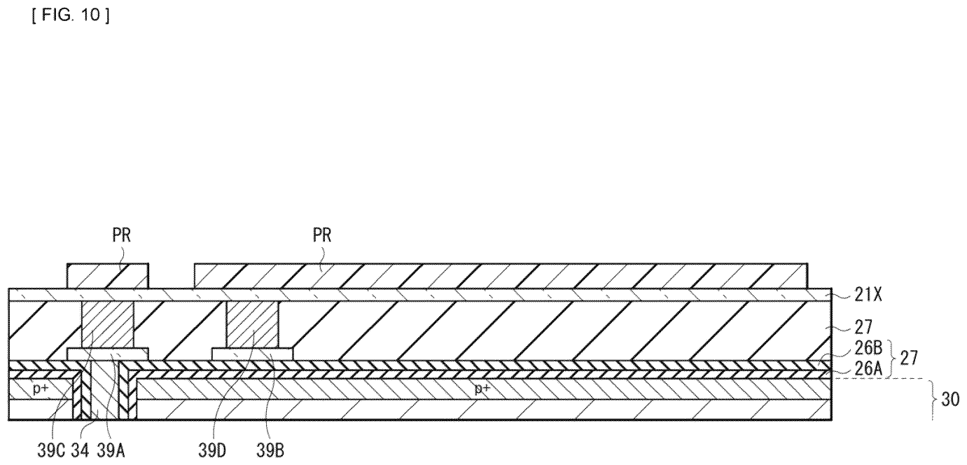

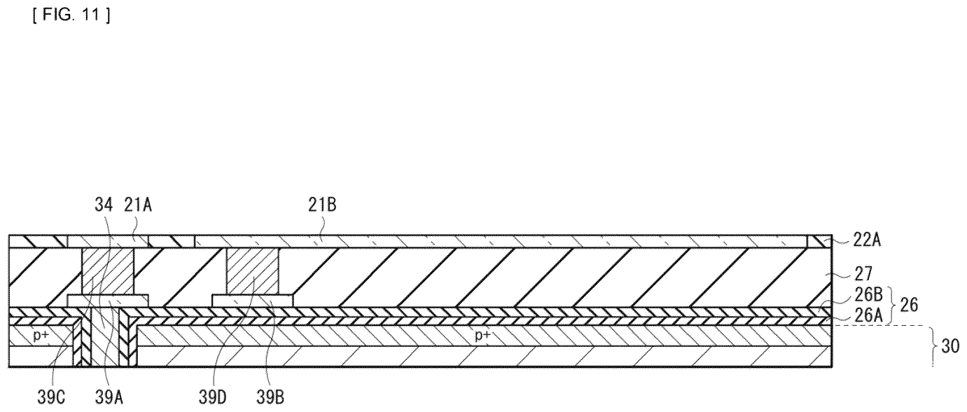

Next, as illustrated in FIG. 10, for example, an electrically-conductive film 21X is formed on the interlayer insulating layer 27 by a sputtering method, and is then patterned using a photolithography technique. Specifically, a photoresist PR is formed at a predetermined position of the electrically-conductive film 21X, and then the electrically-conductive film 21X is worked using dry etching or wet etching. Thereafter, the photoresist PR is removed to thereby form the readout electrode 21A and the accumulation electrode 21B, as illustrated in FIG. 11.

Subsequently, as illustrated in FIG. 11, an insulating layer 22A is embedded around the readout electrode 21A and the accumulation electrode 21B, and is planarized to completely expose the top surfaces of the readout electrode 21A and the accumulation electrode 21B. Specifically, for example, the insulating layer 22A is formed on the entire surface of the pixel section 1A, for example, using a plasma CVD method, and then the insulating layer 22A is planarized using a CMP method.

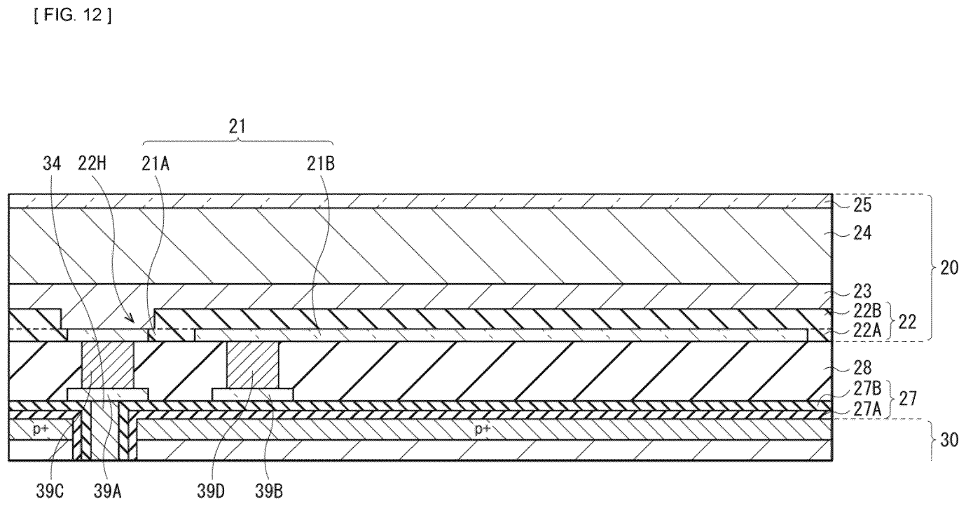

Next, as illustrated in FIG. 12, an insulating layer 22B is formed using, for example, an ALD method, then the photoresist PR is formed at a position above the insulating layer 22B, and then the insulating layer 22B is worked using dry etching or wet etching to form the opening 22H. Thereafter, the oxide semiconductor layer 23, the photoelectric conversion layer 24, and the upper electrode 25 are formed. The oxide semiconductor layer 23 may be formed using a sputtering method, for example. The photoelectric conversion layer 24 is formed using a vacuum deposition method, for example. The upper electrode 25 is formed using a sputtering method, for example, in the same manner as the lower electrode 21. Finally, the on-chip lens 54 and the protective layer 51 including the wiring 52 and the light-blocking film 53 are disposed on the upper electrode 25. As described above, the photodetection element 10 illustrated in FIG. 1 is completed.

It is to be noted that, in a case where another layer including an organic material such as a buffer layer also serving as an electron blocking film, a buffer layer also serving as a hole blocking film, or a work function adjustment layer is formed between the oxide semiconductor layer 23 and the photoelectric conversion layer 24 and between the photoelectric conversion layer 24 and the upper electrode 25 as described above, it is preferable to form the layers continuously (in an in-situ vacuum process) in a vacuum step. In addition, the method of forming the photoelectric conversion layer 24 is not necessarily limited to an approach that uses a vacuum deposition method. For example, a spin coating technique, a printing technique, or the like may be used. Further, examples of a method of forming transparent electrodes (the lower electrode 21 and the upper electrode 25) include, depending on a material constituting the transparent electrode, a physical vapor deposition method (PVD method) such as a vacuum deposition method, a reactive deposition method, an electron beam deposition method, or an ion plating method, a pyrosol method, a method of pyrolyzing an organic metal compound, a spray method, a dip method, various CVD methods including an MOCVD method, an electroless plating method, and an electroplating method, in addition to the sputtering method.

### 1-3. Signal Acquisition Operation in Photodetection Element

When light enters the photoelectric conversion section 20 via the on-chip lens 54 in the photodetection element 10, the light passes through the photoelectric conversion section 20 and the photoelectric conversion regions 32B and 32R in this order. While the light passes through the photoelectric conversion section 20 and the photoelectric conversion regions 32B and 32R, the light is photoelectrically converted for each of color light beams of green (G), blue (B), and red (R). The following describes operations of acquiring signals of the respective colors.

### Acquisition of Green Color Signal by Photoelectric Conversion Section 20

First, green light of the light beams having entered the photodetection element 10 is selectively detected (absorbed) and photoelectrically converted by the photoelectric conversion section 20.

The photoelectric conversion section 20 is coupled to the gate Gamp of the amplifier transistor TR1amp and the floating diffusion FD1 via the through-electrode 34. Thus, electrons of excitons generated by the photoelectric conversion section 20 are taken out from the side of the lower electrode 21, transferred to the side of the second surface 30S2 of the semiconductor substrate 30 via the through-electrode 34, and accumulated in the floating diffusion FD1. At the same time, the amplifier transistor TR1amp modulates the amount of electric charge generated by the photoelectric conversion section 20 to a voltage.

In addition, the reset gate Grst of the reset transistor TR1rst is disposed next to the floating diffusion FD1. This allows the reset transistor TR1rst to reset charge carriers accumulated in the floating diffusion FD1.

The photoelectric conversion section 20 is coupled not only to the amplifier transistor TR1amp, but also to the floating diffusion FD1 via the through-electrode 34, thus enabling the reset transistor TR1rst to easily reset the charge carriers accumulated in the floating diffusion FD1.

In contrast, in a case where the through-electrode 34 and the floating diffusion FD1 are not coupled to each other, it is difficult to reset the charge carriers accumulated in the floating diffusion FD1, thus causing a large voltage to be applied to pull out the charge carriers to a side of the upper electrode 25. The photoelectric conversion layer 24 may therefore be possibly damaged. In addition, a structure that enables resetting in a short period of time leads to an increase in dark noises, resulting in a trade-off. This structure is thus difficult.

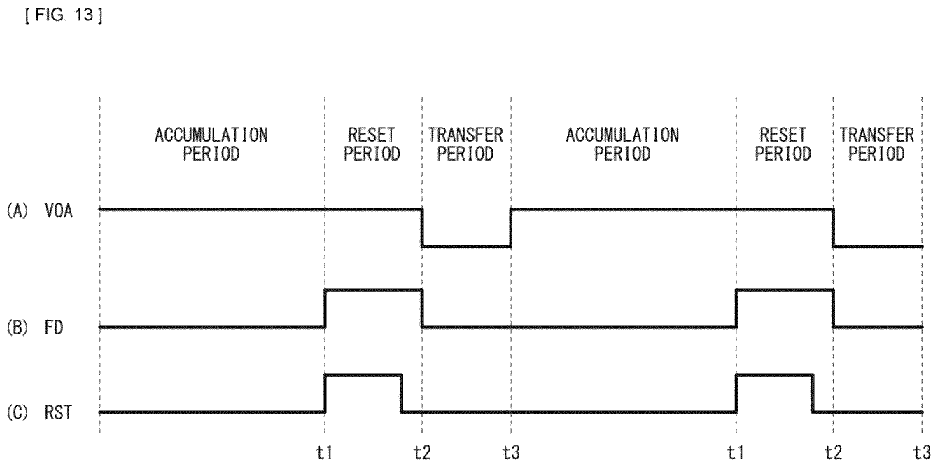

FIG. 13 illustrates an operation example of the photodetection element 10. (A) illustrates a potential at the accumulation electrode 21B, (B) illustrates a potential at the floating diffusion FD1 (readout electrode 21A), and (C) illustrates a potential at the gate (Gsel) of the reset transistor TR1rst. In the photodetection element 10, respective voltages are applied individually to the readout electrode 21A and the accumulation electrode 21b.

In the photodetection element 10, the drive circuit applies a potential V1 to the readout electrode 21A and applies a potential V2 to the accumulation electrode 21B in an accumulation period. Here, it is assumed that the potentials V1 and V2 satisfy V2≥V1, preferably V2>V1. This allows charge carriers (signal charge: electrons) generated through photoelectric conversion to be drawn to the accumulation electrode 21B and to be accumulated in a region of the oxide semiconductor layer 23 opposed to the accumulation electrode 21B (accumulation period). Incidentally, the value of the potential in the region of the oxide semiconductor layer 23 opposed to the accumulation electrode 21B becomes more negative with the passage of time of photoelectric conversion. It is to be noted that holes are sent from the upper electrode 25 to the drive circuit.

In the photodetection element 10, a reset operation is performed in the latter half of the accumulation period. Specifically, at a timing t1, a scanning section changes the voltage of a reset signal RST from a low level to a high level. This brings the reset transistor TR1rst into an ON state in the unit pixel P. As a result, the voltage of the floating diffusion FD1 is set to a power supply voltage, and the voltage of the floating diffusion FD1 is reset (reset period).

After the reset operation is completed, the charge carriers are read. Specifically, the drive circuit applies a potential V3 to the readout electrode 21A and applies a potential V4 to the accumulation electrode 21B at a timing t2. Here, it is assumed that the potentials V3 and V4 satisfy V3>V4. This allows the charge carriers accumulated in the region corresponding to the accumulation electrode 21B to be read from the readout electrode 21 A to the floating diffusion FD1. That is, the charge carriers accumulated in the oxide semiconductor layer 23 are read to the controller (transfer period).

The drive circuit applies the potential V1 to the readout electrode 21A and applies the potential V2 to the accumulation electrode 21B again after the readout operation is completed. This allows charge carriers generated through photoelectric conversion to be drawn to the accumulation electrode 21B and to be accumulated in a region of the photoelectric conversion layer 24 opposed to the accumulation electrode 21B (accumulation period).

### Acquisition of Blue Color Signal and Red Color Signal by Photoelectric Conversion Regions 32B and 32R

Subsequently, the blue light and the red light of the light beams having been transmitted through the photoelectric conversion section 20 are respectively absorbed and photoelectrically converted in order by the photoelectric conversion region 32B and the photoelectric conversion region 32R. In the photoelectric conversion region 32B, electrons corresponding to the incident blue light are accumulated in an n region of the photoelectric conversion region 32B, and the accumulated electrons are transferred to the floating diffusion FD2 by the transfer transistor Tr2. Likewise, in the photoelectric conversion region 32R, electrons corresponding to the incident red light are accumulated in an n region of the photoelectric conversion region 32R, and the accumulated electrons are transferred to the floating diffusion FD3 by the transfer transistor Tr3.

### 1-4. Workings and Effects

The photodetection element 10 of the present embodiment has a configuration in which, in the photoelectric conversion section 20 that includes the lower electrode 21 including the readout electrode 21A and the accumulation electrode 21B, the insulating layer 22, the oxide semiconductor layer 23, the photoelectric conversion layer 24, and the upper electrode 25, which are stacked in this order, the opening 22H provided above the readout electrode 21A in the insulating layer 22 and allowing for electrical coupling between the readout electrode 21A and the oxide semiconductor layer 23 is sized to allow the entire top surface of the readout electrode 21A to be in contact with the oxide semiconductor layer 23 without the insulating layer 22 being interposed therebetween. This is described below.

In recent years, in a CCD image sensor or a CMOS image sensor, the number of photons entering a unit pixel is reduced as a pixel size is reduced, thus causing the sensitivity to be lowered and S/N to be lowered. Further, in the image sensor that is widely used at present, a red pixel, a green pixel, and a blue pixel in which the red, green, and blue primary color filters are respectively located are arranged in a Bayer pattern. However, in each color pixel, light beams other than the corresponding color light (e.g., green light and blue light in the red pixel) are not transmitted through the color filter and are not used for photoelectric conversion, which causes a loss in terms of sensitivity. In addition, there arises a problem of false color caused by performing interpolation processing between pixels to produce a color signal.

As a method for solving these problems, there is known an image sensor in which three layers of photoelectric conversion layers are stacked in a vertical direction to obtain photoelectric conversion signals of three colors in one pixel. As such a structure in which three-color photoelectric conversion layers are stacked in one pixel, for example, an image sensor has been proposed in which a photoelectric conversion section that detects green light and generates signal charge corresponding to the green light is provided above a silicon substrate, and blue light and red light are detected by two PDs stacked in the silicon substrate. Further, in a structure in which one layer of an organic photoelectric conversion film is provided above a silicon substrate and two inorganic photoelectric conversion sections are provided in the silicon substrate, there have been proposed a structure including a back side illumination type structure in which a circuit-forming surface is formed on a side opposite to a light-receiving surface and a structure provided with an oxide semiconductor film and an insulating film that accumulate and transfer electric charge immediately under the photoelectric conversion film and including a plurality of electrodes (a charge readout electrode and a charge accumulation electrode) as the lower electrode.

In the former case, in a case where the organic photoelectric conversion layer is formed as the back side illumination type, no circuit, wiring, or the like is formed between the inorganic photoelectric conversion section and the organic photoelectric conversion section, thus making it possible to shorten the distance between the inorganic photoelectric conversion section and the organic photoelectric conversion section in the same pixel. It is therefore possible to suppress F value dependency of each color, and it is possible to suppress the fluctuation of the sensitivity between the colors. In the latter case, the charge accumulation electrode is located to be opposed to the photoelectric conversion layer with the insulating layer interposed therebetween, thus making it possible to accumulate the electric charge generated through the photoelectric conversion in the oxide semiconductor film. This makes it possible to completely deplete a charge accumulation section at the start of the exposure and to erase the charge. Consequently, it is possible to suppress occurrence of phenomena such as an increase in kTC noise, deterioration in random noise, and a decrease in imaging quality.

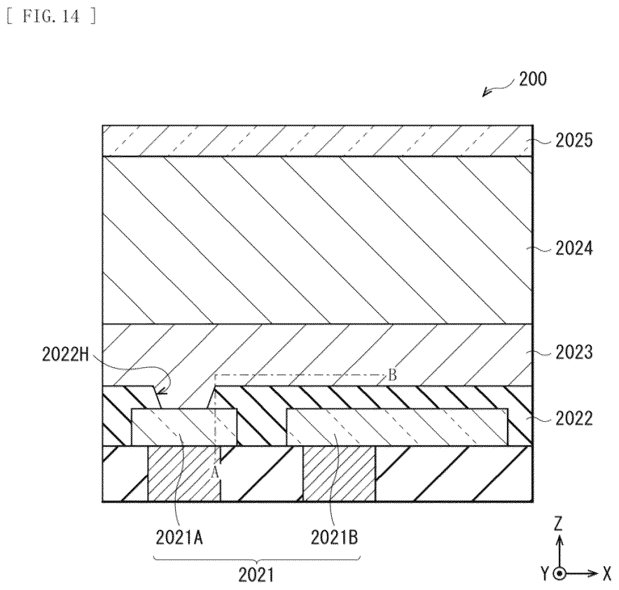

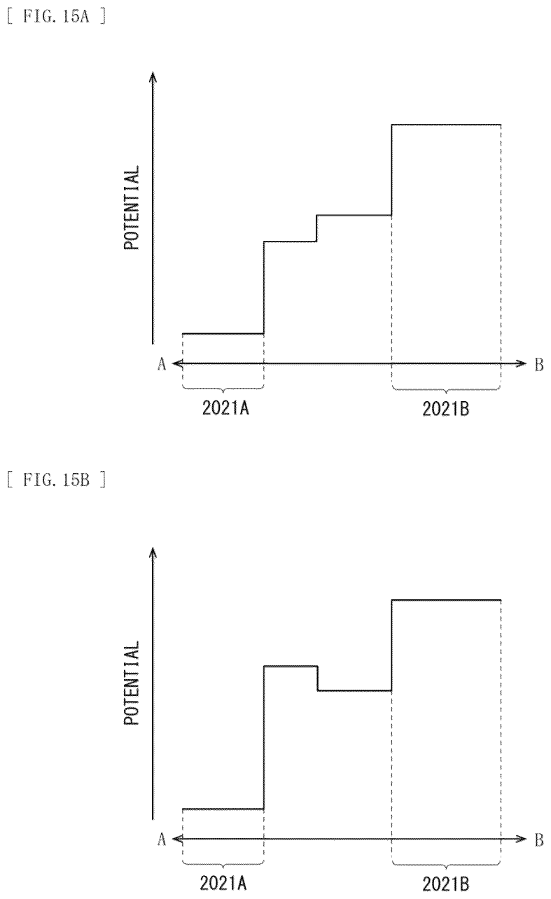

Incidentally, as described above, in an image sensor (e.g., a photoelectric conversion section 200 illustrated in FIG. 14) in which an insulating film and an oxide semiconductor film are stacked between a plurality of electrodes and a photoelectric conversion layer, there is a location in which a parasitic transistor is formed by a readout electrode 2021A being opposed to an oxide semiconductor layer 2023 with an insulating layer 2022 interposed therebetween. A potential between A and B including a part of the parasitic transistor has a stair-like shape, as an initial value, as in the potential diagram at the time of reading illustrated in FIG. 15A. However, a threshold of the parasitic transistor part results in easily varying to a positive side as illustrated in FIG. 15B, for example, due to a stress such as electricity, light, or heat. This variation of the threshold to the positive side causes a barrier between the readout electrode 2021A and an accumulation electrode 2021B, thus inhibiting transfer of charge carriers from the accumulation electrode 2021B to the readout electrode 2021A.

In contrast, in the present embodiment, the opening 22H of the insulating layer 22 is sized to have an area equal to or more than the area of the top surface of the readout electrode 21A to allow the entire top surface of the readout electrode 21A to be in contact with the oxide semiconductor layer 23 without the insulating layer 22 being interposed therebetween. It is therefore possible to prevent the formation of a parasitic transistor between the readout electrode 21A and the oxide semiconductor layer 23. This makes it possible to significantly reduce the inhibition of transfer of charge carriers due to the stress such as electricity, light, or heat.

As described above, it is possible for the photodetection element 10 of the present embodiment to improve reliability.

Next, description is given of a second embodiment and modification examples (Modification Examples 1 to 13) of the present disclosure. Hereinafter, components similar to those of the foregoing embodiment are denoted by the same reference numerals, and descriptions thereof are omitted as appropriate.

### 2. Modification Examples

### 2-1. Modification Example 1

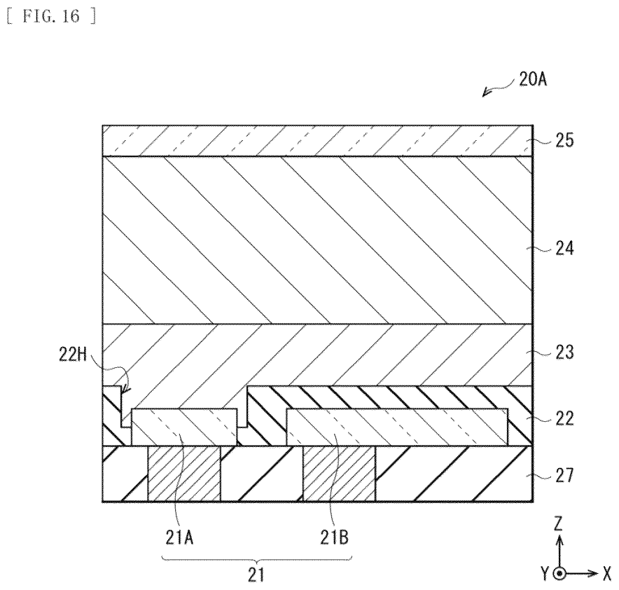

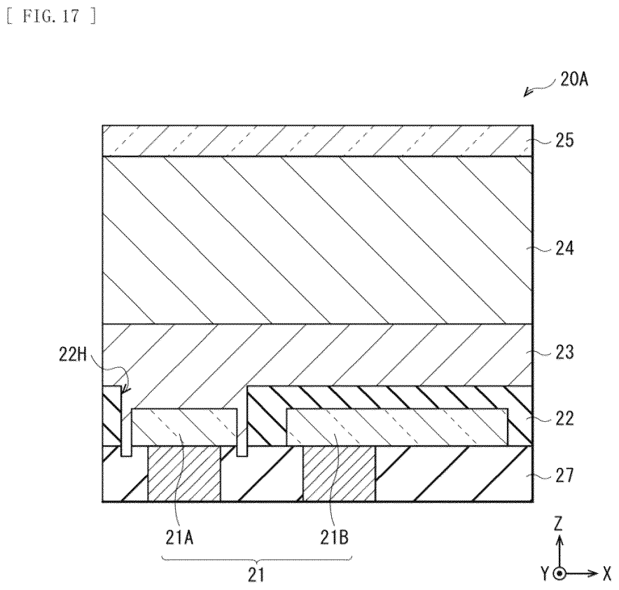

FIG. 16 schematically illustrates an example of a cross-sectional configuration of a main part (a photoelectric conversion section 20A) of a photodetection element according to Modification Example 1 of the present disclosure. FIG. 17 schematically illustrates another example of the cross-sectional configuration of the main part (the photoelectric conversion section 20A) of the photodetection element according to Modification Example 1 of the present disclosure.

The foregoing first embodiment exemplifies the case where the bottom of the opening 22H forms substantially the same plane as the top surface of the readout electrode 21A. In contrast, in the photoelectric conversion section 20A of the present modification example, the bottom of the opening 22H is formed at a position deeper than a side surface of the readout electrode 21A or a bottom surface of the readout electrode 21A. Except these points, the photoelectric conversion section 20A of the present modification example has substantially a similar configuration, in other points, to that of the photoelectric conversion section 20 according to the foregoing first embodiment.

As described above, in the photoelectric conversion section 20A of the modification example, the bottom of the opening 22H is formed at a position deeper than the side surface of the readout electrode 21A or the bottom surface of the readout electrode 21A, to allow the readout electrode 21A and the oxide semiconductor layer 23 to be in contact not only with the top surface of the readout electrode 21A but also with a portion or all of the side surface. This also makes it possible to prevent the formation of a parasitic transistor between the side surface of the readout electrode 21A and the oxide semiconductor layer 23. It is therefore possible to further improve reliability.

### 2-2. Modification Example 2

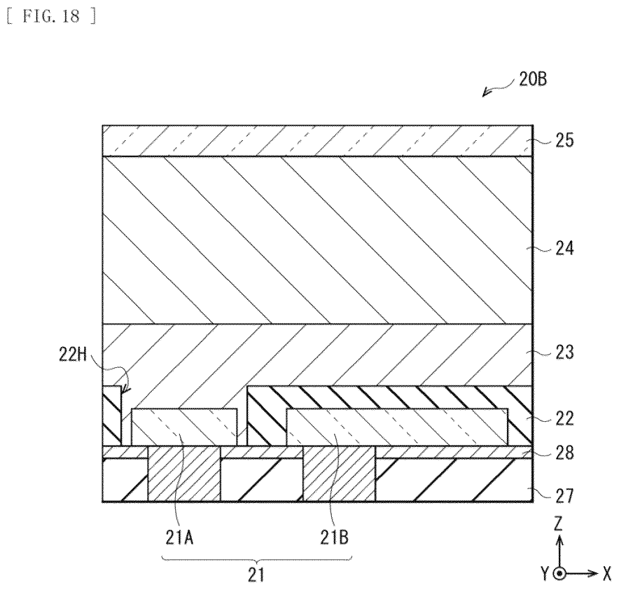

FIG. 18 schematically illustrates an example of a cross-sectional configuration of a main part (a photoelectric conversion section 20B) of a photodetection element according to Modification Example 2 of the present disclosure.

A layer (an etching stopper layer 28) including a material having an etching rate different from that of the insulating layer 22 may be provided between the interlayer insulating layer 27 and the readout electrode 21A as well as the accumulation electrode 21B and between the interlayer insulating layer 27 and the insulating layer 22, as illustrated in FIG. 18. The etching stopper layer 28 corresponds to a specific example of a “second insulating layer” of the present disclosure, and is preferably formed using a material having an etching rate lower than that of the insulating layer 22, for example. This makes it possible to prevent an opening 32H from being overetched to the interlayer insulating layer 27 when being formed.

As described above, in the photoelectric conversion section 20B of the present modification example, the etching stopper layer 28 is provided between the interlayer insulating layer 27 and the readout electrode 21A as well as the accumulation electrode 21B and between the interlayer insulating layer 27 and the insulating layer 22, thus allowing the progress of the etching to be stopped by the etching stopper layer 28. This reduces dispersion of the depth of the opening 22H. It is therefore possible to prevent destabilization of device characteristics, in addition to the effects of the foregoing first embodiment and Modification Example 1.

### 2-3. Modification Example 3

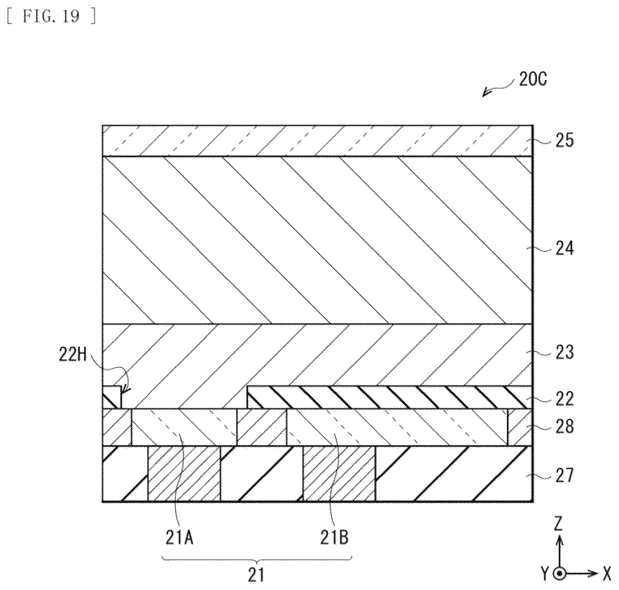

FIG. 19 schematically illustrates an example of a cross-sectional configuration of a main part (a photoelectric conversion section 20C) of a photodetection element according to Modification Example 3 of the present disclosure.

The foregoing Modification Example 2 exemplifies the case where the etching stopper layer 28 is provided between the interlayer insulating layer 27 and the readout electrode 21A as well as the accumulation electrode 21B and between the interlayer insulating layer 27 and the insulating layer 22. In contrast, in the photoelectric conversion section 20C of the present modification example, the etching stopper layer 28 is provided in the same layer as the lower electrode 21 including the readout electrode 21A, the accumulation electrode 21B, and the pixel separation electrode 21C. In other words, the etching stopper layer 28 is embedded among the readout electrode 21A, the accumulation electrode 21B, and the pixel separation electrode 21C. Except this point, the photoelectric conversion section 20C of the present modification example has substantially a similar configuration, in other points, to that of the photoelectric conversion section 20 according to the foregoing first embodiment.

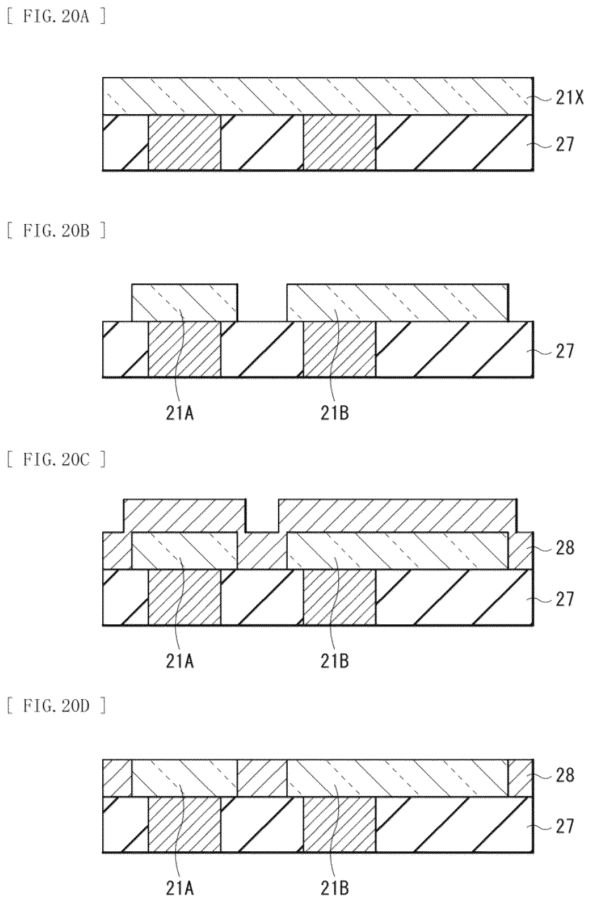

FIGS. 20A to 20D illustrate a method of manufacturing the photoelectric conversion section 20C in the order of steps.

First, as illustrated in FIG. 20A, the electrically-conductive film 21X is formed on the interlayer insulating layer 27 by a sputtering method, for example. Subsequently, as illustrated in FIG. 20B, the readout electrode 21A and the accumulation electrode 21B are formed by patterning using a photolithography technique. Next, as illustrated in FIG. 20C, the etching stopper layer 28 is formed on the entire surface of the pixel section 1A using a plasma CVD method, for example, and then planarized to completely expose the top surfaces of the readout electrode 21A and the accumulation electrode 21B using a CMP method, as illustrated in FIG. 20D. Thereafter, in the same manner as the foregoing first embodiment, the insulating layer 22, the oxide semiconductor layer 23, the photoelectric conversion layer 24, and the upper electrode 25 are formed in order.

As described above, in the photoelectric conversion section 20C of the present modification example, the etching stopper layer 28 is embedded among the readout electrode 21A, the accumulation electrode 21B, and the pixel separation electrode 21C, thus reducing the dispersion of the depth of the opening 22H. It is therefore possible to prevent destabilization of device characteristics, in addition to the effects of the foregoing first embodiment.

### 2-4. Modification Example 4

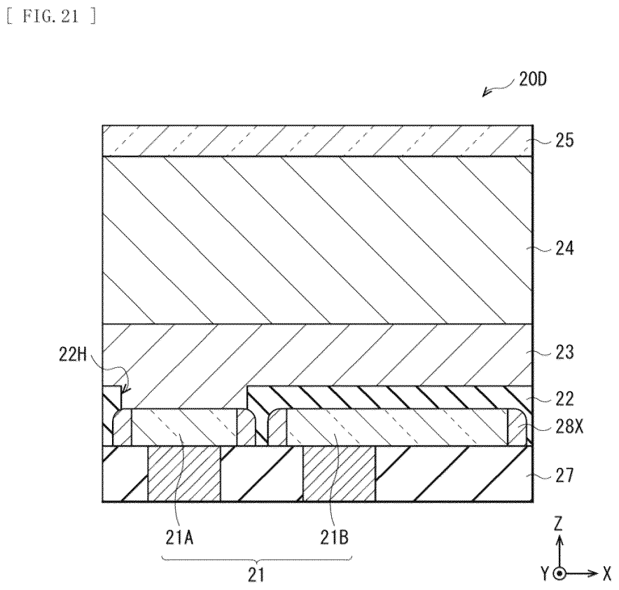

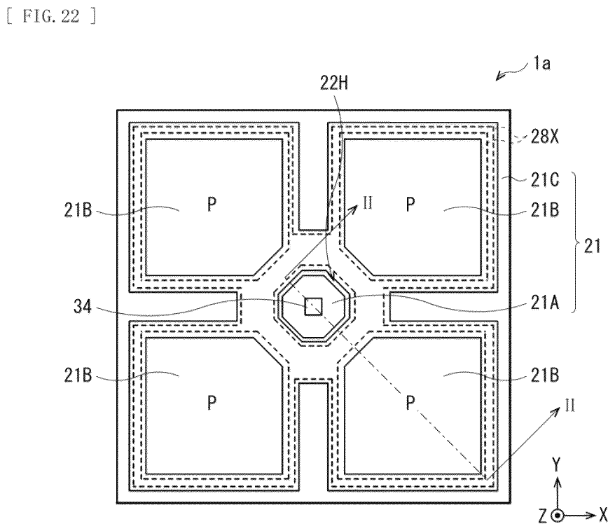

FIG. 21 schematically illustrates an example of a cross-sectional configuration of a main part (a photoelectric conversion section 20D) of a photodetection element according to Modification Example 4 of the present disclosure. FIG. 22 schematically illustrates an example of a pixel configuration of the photodetector 1 including the photoelectric conversion section 20D illustrated in FIG. 21, and FIG. 21 illustrates a cross-section corresponding to a line II-II illustrated in FIG. 22.

The foregoing Modification Example 3 exemplifies the case where the etching stopper layer 28 is embedded among the readout electrode 21A, the accumulation electrode 21B, and the pixel separation electrode 21C. In contrast, in the photoelectric conversion section 20D of the present modification example, a sidewall 28X is provided on side surfaces of the readout electrode 21A, the accumulation electrode 21B, and the pixel separation electrode 21C constituting the lower electrode 21. In the same manner as the above-described etching stopper layer 28, the sidewall 28X includes a material having an etching rate lower than that of the insulating layer 22, for example. Except this point, the photoelectric conversion section 20D of the present modification example has substantially a similar configuration, in other points, to that of the photoelectric conversion section 20 according to the foregoing first embodiment.

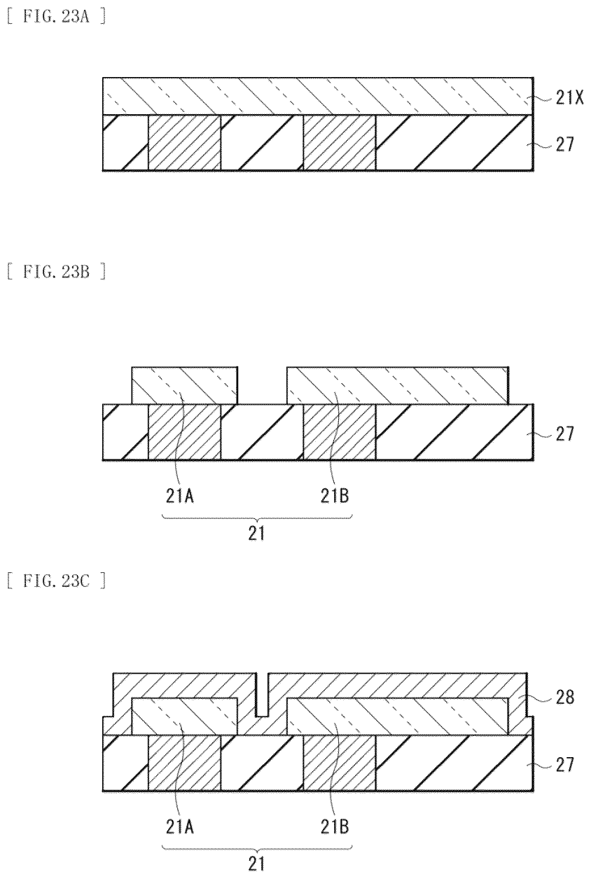

FIGS. 23A to 23F illustrate a method of manufacturing the photoelectric conversion section 20D in the order of steps.

First, as illustrated in FIG. 23A, the electrically-conductive film 21X is formed on the interlayer insulating layer 27 using a sputtering method, for example. Subsequently, as illustrated in FIG. 23B, the readout electrode 21A and the accumulation electrode 21B are formed by patterning using a photolithography technique. Next, as illustrated in FIG. 23C, the etching stopper layer 28 is formed on the entire surface of the pixel section 1A by an ALD method, for example. Subsequently, as illustrated in FIG. 23D, the etching stopper layer 28 is worked anisotropically using dry etching, for example, to allow the etching stopper layer 28 to remain only on the side surfaces of the readout electrode 21A, the accumulation electrode 21B, and the pixel separation electrode 21C. This allows for formation of the sidewall 28X.

Next, as illustrated in FIG. 23E, the etching stopper layer 28 is formed, for example, on the entire surface of the pixel section 1A using a plasma CVD method, for example, and then planarized to completely expose the top surfaces of the readout electrode 21A and the accumulation electrode 21B using a CMP method, as illustrated in FIG. 23F. Thereafter, in the same manner as the foregoing first embodiment, the insulating layer 22, the oxide semiconductor layer 23, the photoelectric conversion layer 24, and the upper electrode 25 are formed in order.

As described above, in the photoelectric conversion section 20D of the present modification example, the sidewall 28X having an etching rate different from that of the insulating layer 22 is provided on the side surfaces of the readout electrode 21A, the accumulation electrode 21B, and the pixel separation electrode 21C, thus reducing the dispersion of the depth of the opening 22H. Therefore, in the same manner as the foregoing Modification Example 2, it is possible to prevent destabilization of device characteristics, in addition to the effects of the foregoing first embodiment.

### 2-5. Modification Example 5

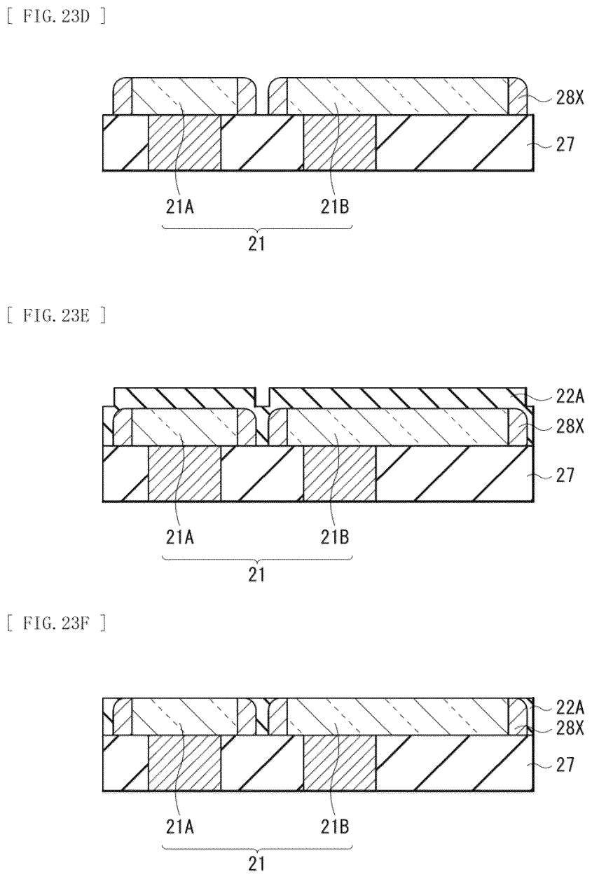

FIG. 24 schematically illustrates an example of a cross-sectional configuration of a main part (a photoelectric conversion section 20E) of a photodetection element according to Modification Example 5 of the present disclosure.

The foregoing first embodiment exemplifies the case where the readout electrode 21 A and the accumulation electrode 21B are formed to have the same thickness. In contrast, in the photoelectric conversion section 20E of the present modification example, the readout electrode 21A is formed to be thicker than the accumulation electrode 21B to allow, for example, the top surface of the readout electrode 21A and a top surface of the insulating layer 22 to form the same plane. Except this point, the photoelectric conversion section 20E of the present modification example has substantially a similar configuration, in other points, to that of the photoelectric conversion section 20 according to the foregoing first embodiment.

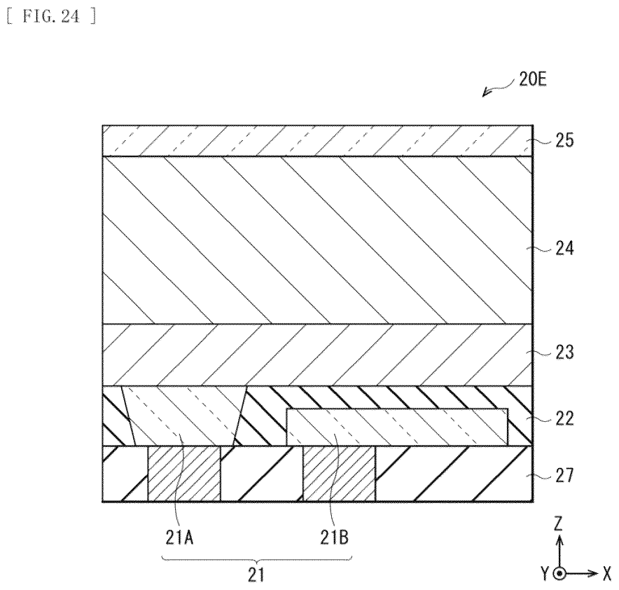

FIGS. 25A to 25D illustrate a method of manufacturing the photoelectric conversion section 20E in the order of steps.

First, in the same manner as the foregoing first embodiment, the electrically-conductive film 21X is formed on the interlayer insulating layer 27 using a sputtering method, for example, and then the accumulation electrode 21B and the pixel separation electrode 21C, which is unillustrated, are formed by patterning using a photolithography technique. Thereafter, in the same manner as the foregoing first embodiment, for example, the insulating layer 22A is formed on the entire surface of the pixel section 1A, for example, using a plasma CVD method, for example, and then planarized to completely expose the top surface of the accumulation electrode 21B using a CMP method, as illustrated in FIG. 25A.

Next, the insulating layer 22B is formed on the accumulation electrode 21B and the insulating layer 22A using a plasma CVD method, for example, and then the opening 22H reaching the interlayer insulating layer 27 is formed using a photolithography technique, as illustrated in FIG. 25B. Subsequently, as illustrated in FIG. 25C, the electrically-conductive film 21X is formed using a sputtering method, for example, and then planarized to expose the top surface of the insulating layer 22 using a CMP method, as illustrated in FIG. 25D. Thereafter, in the same manner as the foregoing first embodiment, the oxide semiconductor layer 23, the photoelectric conversion layer 24, and the upper electrode 25 are formed in order.

As described above, in the photoelectric conversion section 20E of the modification example, the readout electrode 21A is formed to be thicker than the accumulation electrode 21B to allow, for example, the top surface of the readout electrode 21A and the top surface of the insulating layer 22 to form the same plane. This prevents the formation of a parasitic transistor between the readout electrode 21A and the oxide semiconductor layer 23, thus making it possible to obtain similar effects to those of the foregoing first embodiment.

It is to be noted that, in the present modification example, the top surface of the readout electrode 21A is shaped to have an area larger than that of an undersurface thereof. This makes it possible to reduce an influence caused by the formation of a parasitic transistor between the side surface of the readout electrode 21A and the oxide semiconductor layer 23. It is therefore possible to further improve reliability.

### 2-6. Modification Example 6

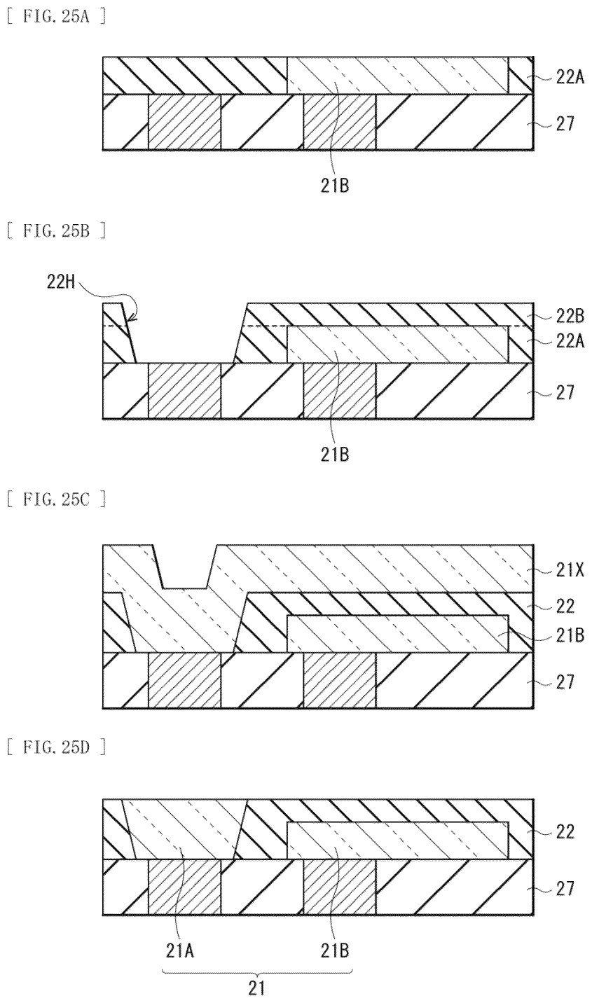

FIG. 26 schematically illustrates an example of a cross-sectional configuration of a main part (a photoelectric conversion section 20F) of a photodetection element according to Modification Example 6 of the present disclosure.

The foregoing first embodiment exemplifies the case where the readout electrode 21 A and the accumulation electrode 21B are formed to have the same thickness. In contrast, in the photoelectric conversion section 20F of the present modification example, a portion of the readout electrode 21A is extended on the side surface of the opening 22H and the insulating layer 22. Except this point, the photoelectric conversion section 20F of the present modification example has substantially a similar configuration, in other points, to that of the photoelectric conversion section 20 according to the foregoing first embodiment.

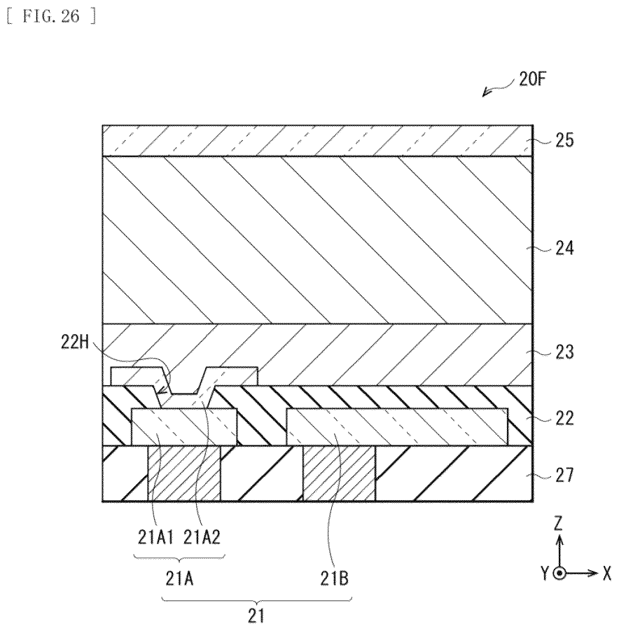

FIGS. 27A to 27D illustrate a method of manufacturing the photoelectric conversion section 20F in the order of steps.

First, in the same manner as the foregoing first embodiment, the electrically-conductive film 21X is formed on the interlayer insulating layer 27 by a sputtering method, for example, and then a readout electrode 21A1 on a lower side and the accumulation electrode 21B are formed by patterning using a photolithography technique. Thereafter, in the same manner as the foregoing first embodiment, the insulating layer 22A is formed on the entire surface of the pixel section 1A, for example, using a plasma CVD method, for example, and then planarized to completely expose the top surfaces of the readout electrode 21A1 and the accumulation electrode 21B using a CMP method, as illustrated in FIG. 27A.

Next, the insulating layer 22B is formed on the readout electrode 21A1, the accumulation electrode 21B, and the insulating layer 22A using a plasma CVD method, for example, and then the opening 22H reaching the readout electrode 21A1 is formed using a photolithography technique, as illustrated in FIG. 27B. Subsequently, as illustrated in FIG. 27C, the electrically-conductive film 21X to serve as a readout electrode 21A2 on an upper side is formed using a sputtering method, for example. Thereafter, the electrically-conductive film 21X is patterned using a photolithography technique, and, as illustrated in FIG. 27D, the readout electrode 21A2 on the upper side is worked. At that time, it is preferable that the end of the readout electrode 21A extending on the insulating layer 22 be formed inside the dotted line region illustrated in FIG. 2. This makes it possible to easily control the potential between the readout electrode 21A and the accumulation electrode 21B. Thereafter, in the same manner as the foregoing first embodiment, the oxide semiconductor layer 23, the photoelectric conversion layer 24, and the upper electrode 25 are formed in order.

As described above, in the photoelectric conversion section 20F of the present modification example, a portion of the readout electrode 21A is extended on the side surface of the opening 22H and the insulating layer 22. This eliminates a location where the readout electrode 21A, the insulating layer 22, and the oxide semiconductor layer 23 are stacked, as viewed from the top surface. This prevents the formation of a parasitic transistor between the readout electrode 21A and the oxide semiconductor layer 23, thus making it possible to obtain similar effects to those of the foregoing first embodiment.

### 2-7. Modification Example 7

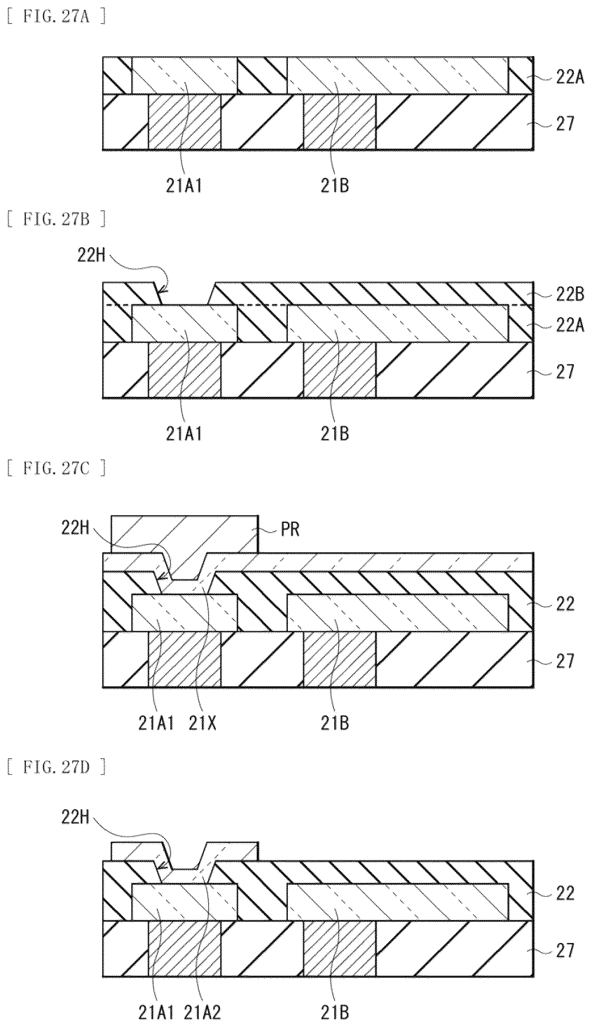

FIG. 28 schematically illustrates an example of a cross-sectional configuration of a main part (a photoelectric conversion section 20G) of a photodetection element according to Modification Example 7 of the present disclosure. The photoelectric conversion section 20G of the present modification example includes an inorganic buffer layer 29 provided between the oxide semiconductor layer 23 and the photoelectric conversion layer 24. Except this point, the photoelectric conversion section 20G of the present modification example has substantially a similar configuration, in other points, to that of the photoelectric conversion section 20 according to the foregoing first embodiment.

The inorganic buffer layer 29 is provided to prevent desorption of oxygen from the oxide semiconductor layer 23. The inorganic buffer layer 29 may be formed using a metal oxide, for example. Examples of the metal oxide include an oxide material including at least one element of tantalum (Ta), titanium (Ti), vanadium (V), niobium (Nb), tungsten (W), zirconium (Zr), hafnium (Hf), scandium (Sc), yttrium (Y), lanthanum (La), gallium (Ga), or magnesium (Mg). Specific examples thereof include Ta₂O₅, TiO₂, V₂O₅, Nb₂O₅, W₂O₃, ZrO₂, HfO₂, Sc₂O₃, Y₂O₃, La₂O₃, Ga₂O₃, and MgO.

The inorganic buffer layer 29 has a thickness of 1 atomic layer or more and 2 nm or less, for example.

Alternatively, a tunnel oxide film may be used for the inorganic buffer layer 29. The tunnel oxide film may be formed using SiOₓ, SiON, SiOC, or AlOₓ, for example. The inorganic buffer layer 29 may be a metal oxide film, a tunnel oxide film, or an ON stacked film. If the inorganic buffer layer 29 is defined, with a vacuum level being set as a zero standard, to have higher energy as being away from the vacuum level, when a minimum energy value of a conduction band of a material constituting the oxide semiconductor layer 23 is set as Ec_c, a minimum energy value of a conduction band of a material constituting the inorganic buffer layer 29 is set as Ec_a, and a LUMO (Lowest Unoccupied Molecular Orbital) value of a material constituting the photoelectric conversion layer 24 is set as Ec_o, it is preferable that the following expression (1):

$$Ec\_o \leq Ec\_b \leq Ec\_a \leq Ec\_c \qquad ( 1 )$$

be satisfied.

As described above, in the present modification example, the inorganic buffer layer 29 is provided between the oxide semiconductor layer 23 and the photoelectric conversion layer 24, thus making it possible to reduce the desorption of oxygen from the surface of the oxide semiconductor layer 23. In addition, the generation of a trap at the interface between the oxide semiconductor layer 23 and the photoelectric conversion layer 24 is further reduced. Furthermore, it becomes possible to prevent backflow of signal charge (electrons) from a side of the oxide semiconductor layer 23 to the photoelectric conversion layer 24. It is therefore possible to improve residual image characteristics, in addition to the effects of the foregoing first embodiment.

### 2-8. Modification Example 8

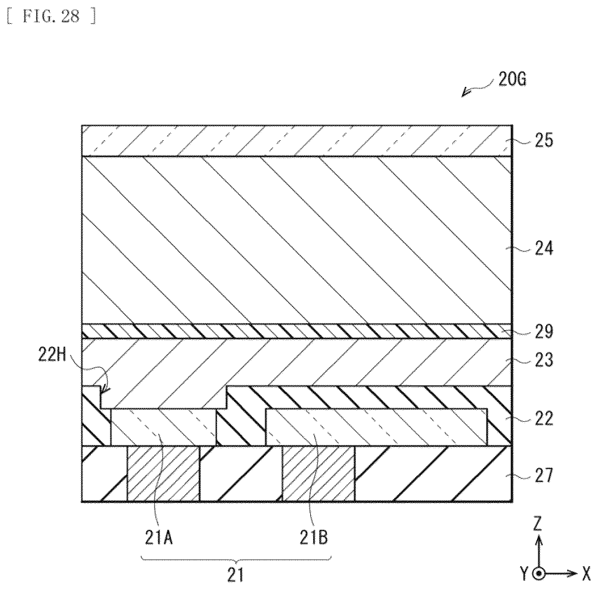

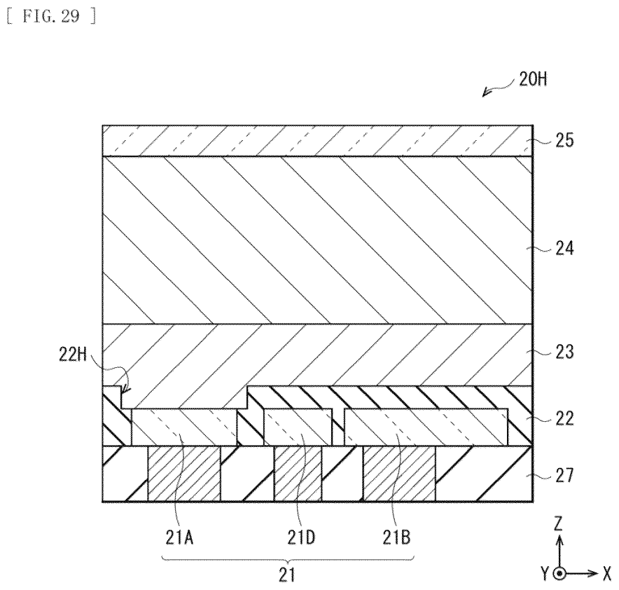

FIG. 29 schematically illustrates an example of a cross-sectional configuration of a main part (a photoelectric conversion section 20H) of a photodetection element according to Modification Example 8 of the present disclosure. FIG. 30 schematically illustrates an example of a pixel configuration of the photodetector 1 including the photoelectric conversion section 20H illustrated in FIG. 29, and FIG. 29 illustrates a cross-section corresponding to a line I-I illustrated in FIG. 30. The photoelectric conversion section 20H of the present modification example includes a transfer electrode 21D provided between the readout electrode 21 A and the accumulation electrode 21B. Except this point, the photoelectric conversion section 20H of the present modification example has substantially a similar configuration, in other points, to that of the photoelectric conversion section 20 according to the foregoing first embodiment.

The transfer electrode 21D corresponds to a specific example of a “fourth electrode” of the present disclosure. The transfer electrode 21D is provided to improve transfer efficiency of electric charge accumulated above the accumulation electrode 21B to the readout electrode 21A. The transfer electrode 21D is provided between the readout electrode 21A and the accumulation electrode 21B. At that time, an end of the bottom of the opening 22H is provided outside the end of the top surface of the readout electrode 21A, and is formed on a side of the readout electrode 21A between the end of the readout electrode 21A and an end of the transfer electrode 21D which are opposed to each other. In other words, the end of the bottom of the opening 22H is provided outside the end of the top surface of the readout electrode 21A, and is formed at a position that allows the minimum distance between the end of the bottom of the opening 22H and the end of the top surface of the readout electrode 21A to be smaller than a minimum distance between the end of the bottom of the opening 22H and an end of a top surface of the transfer electrode 21D. This makes it possible to easily control a potential between the readout electrode 21A and the transfer electrode 21D.

It is to be noted that, as for the transfer electrode 21D, as illustrated in FIG. 30, the transfer electrode 21D may be provided at a location between each of four accumulation electrodes 21B and the readout electrode 21A. The four accumulation electrodes 21B are arranged at four corners around the readout electrode 21A in the pixel unit 1a including four pixels arranged in 2 rows×2 columns. Alternatively, four transfer electrodes 21D each provided between each of the four accumulation electrodes 21B and the readout electrode 21A may be integrally formed into a rhombic shape, for example.

The readout electrode 21A, the accumulation electrode 21B, the pixel separation electrode 21C, and the transfer electrode 21D are configured to apply voltages independently of one another. In the present modification example, the drive circuit applies a potential V5 to the readout electrode 21A, a potential V6 to the accumulation electrode 21B, and a potential V7 to the transfer electrode 21D (V5>V6>V7) during the transfer period after completion of the reset operation. This allows the electric charge accumulated above the accumulation electrode 21B to move from the location above the accumulation electrode 21B to a location above the transfer electrode 21D and to a location above the readout electrode 21A in this order and to be read to the floating diffusion FD1.

As described above, in the present modification example, the transfer electrode 21D is provided between the readout electrode 21A and the accumulation electrode 21B. This makes it possible to move electric charge from the readout electrode 21A to floating diffusion FD1 more securely. It is therefore possible to improve transfer characteristics and residual image characteristics, in addition to the effects of the foregoing first embodiment.

### 2. Second Embodiment

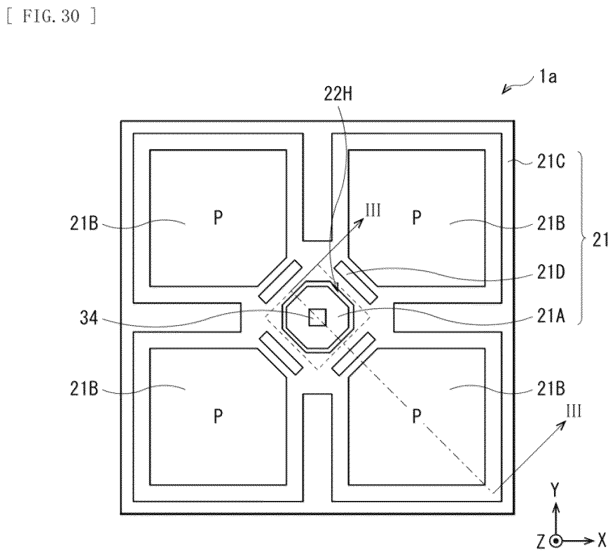

FIG. 31 illustrates a cross-sectional configuration of a main part (a photoelectric conversion section 60) of a photodetection element according to a second embodiment of the present disclosure. In the same manner as the photoelectric conversion section 20 of the foregoing first embodiment, the photoelectric conversion section 60 constitutes, for example, as the photodetection element 10 together with the two photoelectric conversion regions 32B and 32R, one pixel (unit pixel P) repeatedly arranged in array in the pixel section 1A of a photodetector (e.g., the photodetector 1; see FIG. 29) such as a CMOS image sensor used for an electronic apparatus such as a digital still camera or a video camera, for example.

The photoelectric conversion section 60 of the present embodiment includes a lower electrode 61 including a readout electrode 61A and an accumulation electrode 61B, an insulating layer 62, an oxide semiconductor layer 63, a photoelectric conversion layer 64, and an upper electrode 65, which are stacked in this order. In the present embodiment, a work function adjustment layer 68 is provided on the readout electrode 61A. The work function adjustment layer 68 is configured to be provided between the readout electrode 61A and the insulating layer 62 at a location where the readout electrode 61A and the insulating layer 62 are stacked outside an opening 62H. This readout electrode 61A corresponds to a specific example of the “first electrode” of the present disclosure, the accumulation electrode 61B corresponds to a specific example of the “first electrode” of the present disclosure, and the lower electrode 61 including the readout electrode 61A and the accumulation electrode 61B corresponds to a specific example of the “electrode layer” of the present disclosure. The upper electrode 65 corresponds to a specific embodiment of the “third electrode” of the present disclosure. In addition, the insulating layer 62 corresponds to a specific example of the “first insulating layer” of the present disclosure, the opening 62H corresponds to a specific example of the “opening” of the present disclosure, and the work function adjustment layer 68 corresponds to a “work function adjustment layer” of the present disclosure.

### 3-1. Configuration of Photoelectric Conversion Section

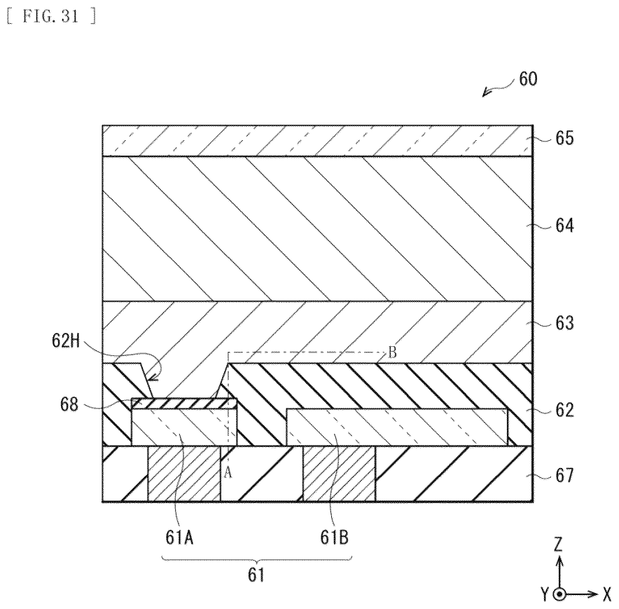

FIG. 32 schematically illustrates an example of a pixel configuration of the photodetector 1 including the photoelectric conversion section 60 illustrated in FIG. 31, and FIG. 31 illustrates a cross-section corresponding to a line IV-IV illustrated in FIG. 32. In the photoelectric conversion section 60, the oxide semiconductor layer 63 and the photoelectric conversion layer 64 formed using an organic material are stacked in this order from a side of the lower electrode 61, between the lower electrode 61 and the upper electrode 65 disposed to be opposed to each other. The photoelectric conversion section 60 further includes the insulating layer 62 between the lower electrode 61 and the oxide semiconductor layer 63.

The lower electrode 61, the insulating layer 62, the oxide semiconductor layer 63, the photoelectric conversion layer 64, and the upper electrode 65 that constitute the photoelectric conversion section 60 have similar configurations to those of the photoelectric conversion section 20 in the foregoing first embodiment, and thus descriptions thereof are omitted in the present embodiment.

The opening 62H provided above the readout electrode 61A in the insulating layer 62 and allowing for electrical coupling between the readout electrode 61A and the oxide semiconductor layer 63 is shaped to allow a portion of a top surface of the readout electrode 61A to be exposed to the bottom of the opening 62H, as illustrated in FIG. 32. The readout electrode 61A, the insulating layer 62, and the oxide semiconductor layer 63 are stacked outside the opening 62H.

The work function adjustment layer 68 is provided to prevent transfer failure of charge carriers due to a variation in the threshold of the parasitic transistor part formed at a location where the readout electrode 61A, the insulating layer 62, and the oxide semiconductor layer 63 are stacked. Examples of a constituent material of the work function adjustment layer 68 include an oxide materials including at least one of silicon (Si), germanium (Ge), tantalum (Ta), titanium (Ti), vanadium (V), niobium (Nb), tungsten (W), zirconium (Zr), hafnium (Hf), scandium (Sc), yttrium (Y), strontium (Sr), or lanthanum (La).

It is to be noted that, in the work function adjustment layer 68, a dipole is preferably formed that allows for negative electric charge on a side of the work function adjustment layer 68 with respect to the insulating layer 62. For example, in a case where the insulating layer 62 is formed using SiO₂, the work function adjustment layer 68 is preferably formed using Y₂O₃, Sr₂O₃, or La₂O₃.

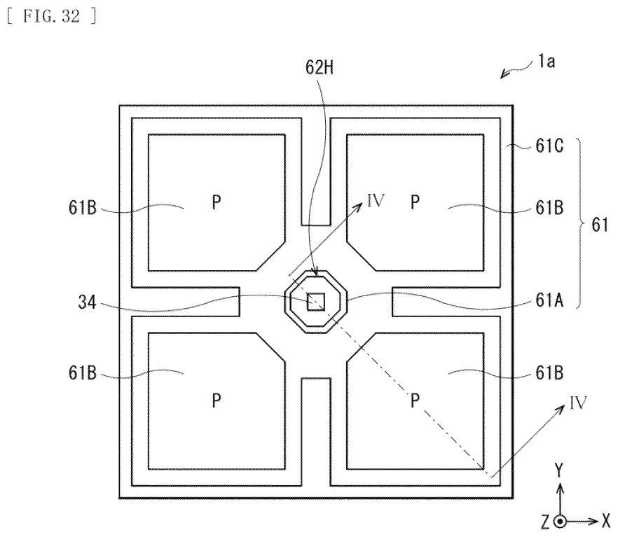

FIG. 33 illustrates an example of a potential between A and B illustrated in FIG. 31 at the time of reading. Providing the work function adjustment layer 68 between the readout electrode 61A and the insulating layer 62 causes the threshold of the parasitic transistor, which is formed between the readout electrode 61A and the insulating layer 62, to be shifted to a negative side. Accordingly, as illustrated in FIG. 33, even in a case where the threshold of the parasitic transistor is shifted to a positive side (an arrow direction in the drawing) due to a stress such as electricity, light, or heat, the formation of a barrier between the readout electrode 61A and the accumulation electrode 61B is prevented.

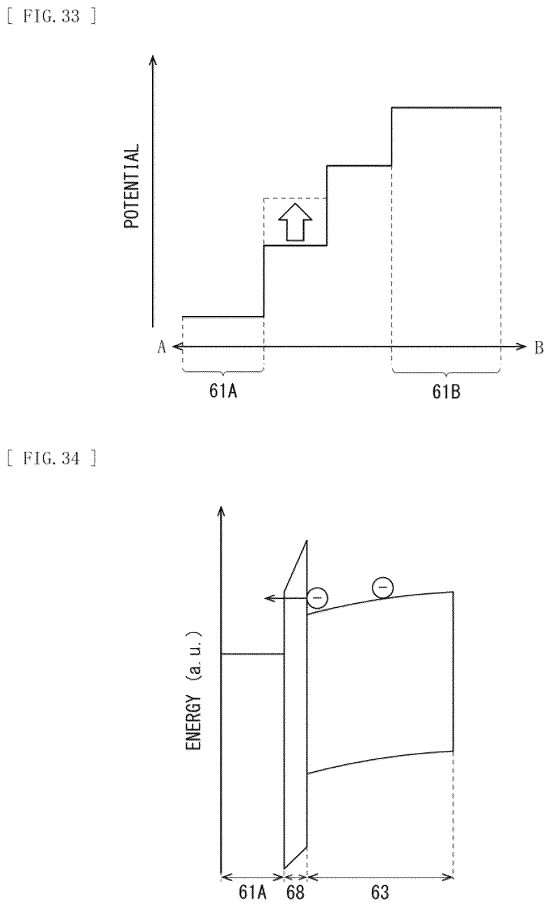

In addition, the work function adjustment layer 68 is preferably a tunnel film, as illustrated in FIG. 34. In order to cause the work function adjustment layer 68 to serve as a tunnel film, the work function adjustment layer 68 preferably has a thickness of 1 atomic layer or more and less than 2 nm.

### 3-2. Workings and Effects

In the photoelectric conversion section 60 of the present embodiment, the work function adjustment layer 68 is provided on the readout electrode 61A, and the readout electrode 61A, the work function adjustment layer 68, the insulating layer 62, and the oxide semiconductor layer 63 are stacked outside the opening 62H. This causes the threshold of the parasitic transistor, which is formed between the readout electrode 61A and the insulating layer 62, to be shifted to the negative side, thus making it possible to increase a margin for the variation in the threshold of the parasitic transistor part. That is, even in a case where the threshold of the parasitic transistor is shifted to the positive side (the arrow direction in the drawing) due to the stress such as electricity, light, or heat, it is possible to significantly reduce the transfer failure of charge carriers.

As described above, it is possible to improve reliability in the photodetection element 10 of the present embodiment.

### 4. Modification Examples

### 4-1. Modification Example 9

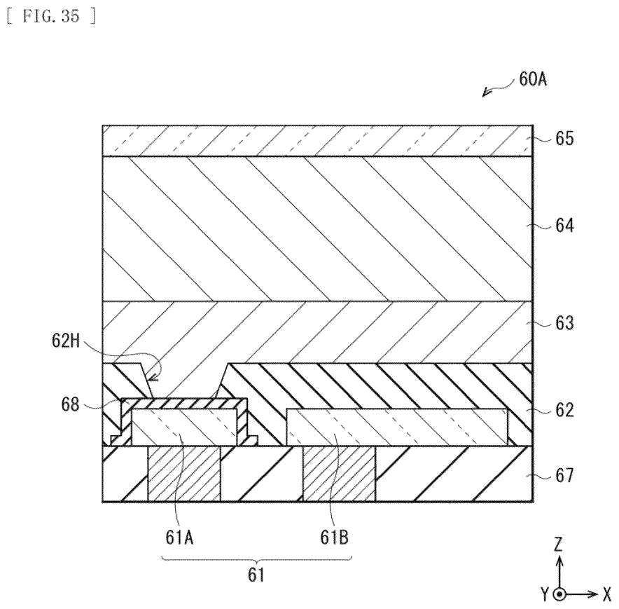

FIG. 35 schematically illustrates an example of a cross-sectional configuration of a main part (a photoelectric conversion section 60A) of a photodetection element according to Modification Example 9 of the present disclosure.

The foregoing second embodiment exemplifies the work function adjustment layer 68 being provided on the top surface of the readout electrode 61A. In contrast, in the photoelectric conversion section 60A of the present modification example, the work function adjustment layer 68 is provided from the top surface to a side surface of the readout electrode 61A. Except this point, the photoelectric conversion section 60A of the present modification example has substantially a similar configuration, in other points, to that of the photoelectric conversion section 60 according to the foregoing second embodiment.

As described above, in the photoelectric conversion section 60A of the present modification example, the work function adjustment layer 68 is formed to coat the top surface and the side surface of the readout electrode 61A. This makes it possible to prevent the formation of a parasitic transistor between the side surface of the readout electrode 61A and the oxide semiconductor layer 63. It is therefore possible to further improve reliability.

### 4-2. Modification Example 10

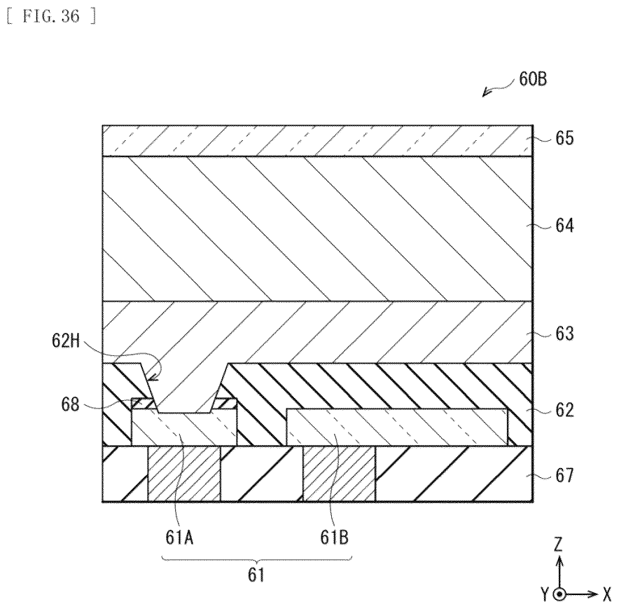

FIG. 36 schematically illustrates an example of a cross-sectional configuration of a main part (a photoelectric conversion section 60B) of a photodetection element according to Modification Example 10 of the present disclosure.

The foregoing second embodiment exemplifies the work function adjustment layer 68 being provided on the entire top surface of the readout electrode 61A. In contrast, in the photoelectric conversion section 60A of the present modification example, the work function adjustment layer 68 at the bottom of the opening 62H is etched to expose the readout electrode 61A. Except this point, the photoelectric conversion section 60A of the present modification example has substantially a similar configuration, in other points, to that of the photoelectric conversion section 60 according to the foregoing second embodiment.

As described above, in the photoelectric conversion section 60B of the present modification example, the readout electrode 61A is exposed at the bottom of the opening 62H. Also in such a configuration, it is possible to obtain similar effects to those of the foregoing second embodiment.

### 4-3. Modification Example 11

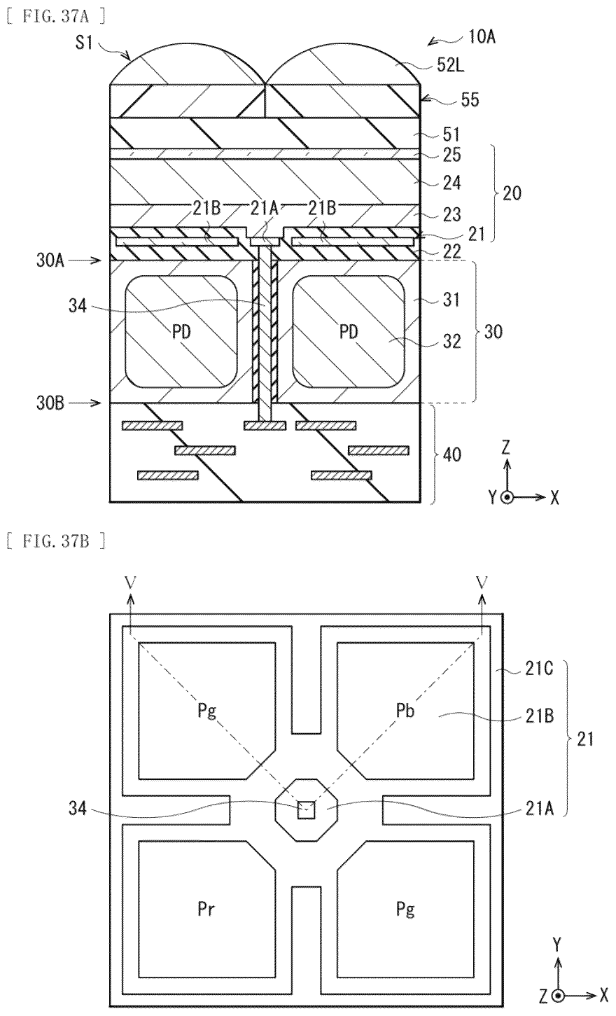

FIG. 37A schematically illustrates a cross-sectional configuration of a photodetection element 10A according to Modification Example 11 of the present disclosure. FIG. 37B schematically illustrates an example of a planar configuration of the photodetection element 10A illustrated in FIG. 37A, and FIG. 37A illustrates s a cross-section taken along a line V-V illustrated in FIG. 37B. The photodetection element 10A is, for example, a stacked photodetection element in which a photoelectric conversion region 32 and the photoelectric conversion section 20 are stacked. In the pixel section 1A of a photodetector (e.g., the photodetector 1) including the photodetection element 10A, for example, the pixel unit 1a including four pixels arranged in two rows x two columns serves as a repeating unit, and is repeatedly arranged in an array including a row direction and a column direction, for example, as illustrated in FIG. 37B.

The photodetection element 10A according to the present modification example is provided with color filters 55 above the photoelectric conversion sections 20 (light incident side S1) for the respective unit pixels P. The respective color filters 55 selectively transmit red light (R), green light (G), and blue light (B). Specifically, in the pixel unit 1a including four pixels arranged in two rows×two columns, two color filters each of which selectively transmits green light (G) are arranged on a diagonal line, and color filters that selectively transmit red light (R) and blue light (B) are arranged one by one on orthogonal diagonal lines. The unit pixels (Pr, Pg, and Pb) provided with the respective color filters each detect corresponding color light, for example, in the photoelectric conversion section 20. That is, the respective pixels (Pr, Pg, and Pb) that detect red light (R), green light (G), and blue light (B) are arranged in a Bayer arrangement in the pixel section 1A.

For example, the photoelectric conversion section 20 absorbs light beams corresponding to some or all of wavelengths of a visible light region of 400 nm or more and less than 750 nm to generate excitons (electron-hole pairs). In the photoelectric conversion section 20, the lower electrode 21, the insulating layer 22, the oxide semiconductor layer 23, the photoelectric conversion layer 24, and the upper electrode 25 are stacked in this order. The photoelectric conversion section 20 has a similar configuration to that of the foregoing first embodiment, for example. The lower electrode 21 includes, for example, the readout electrode 21A and the accumulation electrode 21B which are independently of each other, and the readout electrode 21A is shared by four pixels, for example.

The photoelectric conversion region 32 detects an infrared light region of 700 nm or more and 1000 nm or less, for example.

In the photodetection element 10A, light beams (red light (R), green light (G), and blue light (B)) in a visible light region of the light beams transmitted through the color filters 55 are absorbed by the photoelectric conversion sections 20 of the unit pixels (Pr, Pg, and Pb) provided with the respective color filters. Another light, e.g., light (infrared light (IR)) in an infrared light region (e.g., 700 nm or more and 1000 nm) is transmitted through the photoelectric conversion sections 20. The infrared light (IR) transmitted through the photoelectric conversion section 20 is detected by the photoelectric conversion region 32 of each of the unit pixels Pr, Pg, and Pb. Each of the unit pixels Pr, Pg, and Pb generates signal charge corresponding to the infrared light (IR). That is, the photodetector 1 including the photodetection element 10A is able to concurrently generate both a visible light image and an infrared light image.

In addition, it is possible for the photodetector 1 including the photodetection element 10A to acquire the visible light image and the infrared light image at the same position in an X-Z in-plane direction. It is therefore possible to achieve higher integration in the X-Z in-plane direction

### 4-4. Modification Example 12

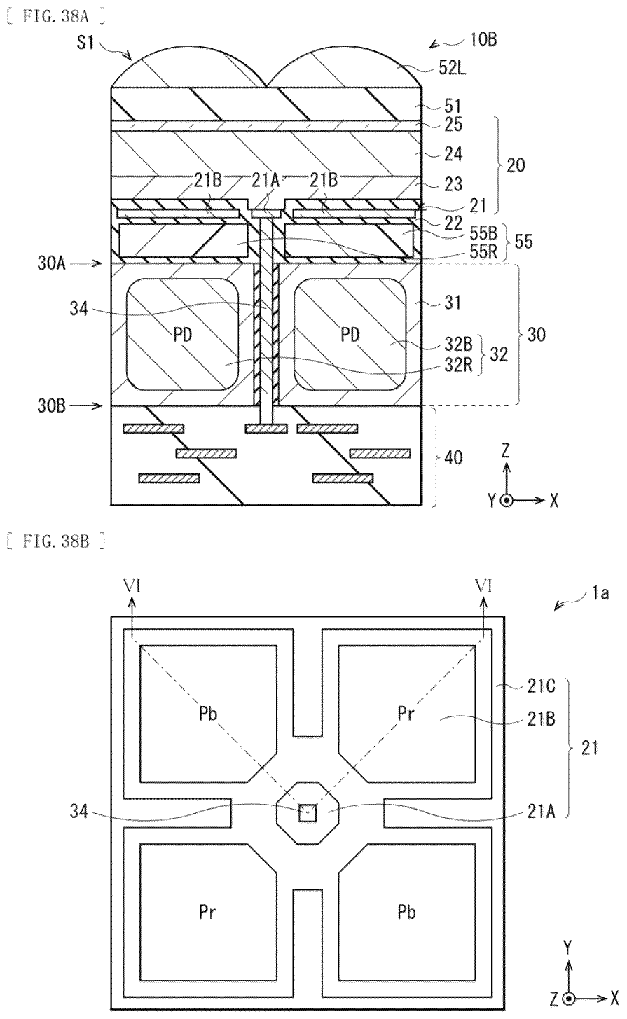

FIG. 38A schematically illustrates a cross-sectional configuration of a photodetection element 10B according to Modification Example 12 of the present disclosure. FIG. 38B schematically illustrates an example of a planar configuration of the photodetection element 10B illustrated in FIG. 38A. FIG. 38A illustrates a cross-section taken along a line VI-VI illustrated in FIG. 38B. The foregoing Modification Example 4 exemplifies the color filters 55 being provided above the photoelectric conversion section 20 (light incident side S1), but the color filters 55 may be each provided between the photoelectric conversion region 32 and the photoelectric conversion section 20, for example, as illustrated in FIG. 38A.

For example, the photodetection element 10B has a configuration in which color filters (color filters 55R) each of which selectively transmits at least red light (R) and color filters (color filters 55B) each of which selectively transmits at least blue light (B) are arranged on the respective diagonal lines in the pixel unit 1a. The photoelectric conversion section 20 (photoelectric conversion layer 64) is configured to selectively absorb light having a wavelength corresponding to green light (G), for example. Light having a wavelength corresponding to red light (R) is selectively absorbed in the photoelectric conversion region 32R, and light having a wavelength corresponding to blue light (B) is selectively absorbed in the photoelectric conversion region 32B. This enables the photoelectric conversion sections 20 and the respective photoelectric conversion regions 32 (photoelectric conversion regions 32R and 32G) arranged below the color filters 55R and 55B to acquire signals corresponding to red light (R), green light (G), or blue light (B). The photodetection element 10B according to the present modification example enables the respective photoelectric conversion sections of R, G, and B to each have a larger area than that of the photoelectric conversion element having a typical Bayer arrangement. This makes it possible to improve an S/N ratio.

### 4-5. Modification Example 13

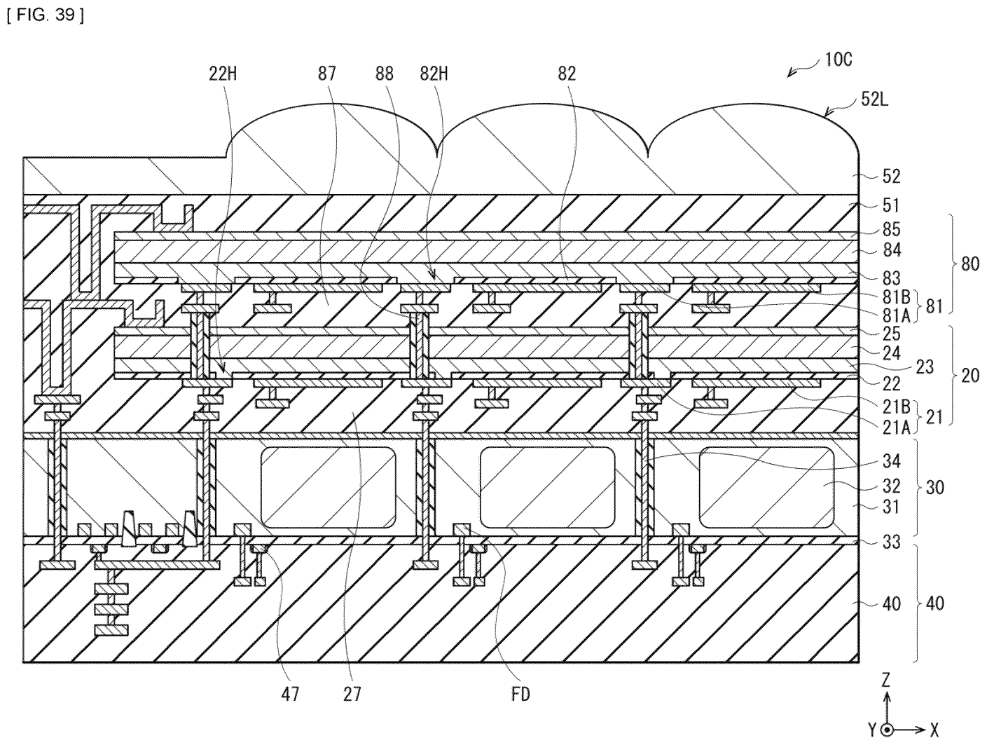

FIG. 39 schematically illustrates a cross-sectional configuration of a photodetection element 10C according to Modification Example 13 of the present disclosure. In the photodetection element 10C of the present modification example, two photoelectric conversion sections 20 and 80 and one photoelectric conversion region 32 are stacked in the vertical direction.

The photoelectric conversion sections 20 and 80 and the photoelectric conversion region 32 selectively detect light beams in wavelength regions different from each other to perform photoelectric conversion. For example, the photoelectric conversion section 20 acquires a color signal of green (G). For example, the photoelectric conversion section 80 acquires a color signal of blue (B). For example, the photoelectric conversion region 32 acquires a color signal of red (R). This enables the photodetection element 10C to acquire a plurality of types of color signals in one pixel without using a color filter.

The photoelectric conversion section 80 is stacked above the photoelectric conversion section 20, for example, and has a configuration similar to that of the photoelectric conversion section 20. Specifically, the photoelectric conversion section 80 includes a lower electrode 81, an insulating layer 82, a semiconductor layer 83, a photoelectric conversion layer 84, and an upper electrode 85, which are stacked in this order. In the same manner as the photoelectric conversion section 20, the lower electrode 81 includes a plurality of electrodes (e.g., a readout electrode 81A and an accumulation electrode 81B), and electrically separated by the insulating layer 82. In the same manner as the opening 22H, the insulating layer 82 is provided with an opening 82H larger than the readout electrode 81A. The readout electrode 81A and the semiconductor layer 83 are electrically coupled to each other via the opening 82H. An interlayer insulating layer 87 is provided between the photoelectric conversion section 80 and the photoelectric conversion section 20.

A through-electrode 88 is coupled to the readout electrode 81A. The through-electrode 88 penetrates the interlayer insulating layer 87 and the photoelectric conversion section 20, and is electrically coupled to the readout electrode 21A of the photoelectric conversion section 20. Further, the readout electrode 81A is electrically coupled to the floating diffusion FD provided in the semiconductor substrate 30 via the through-electrodes 34 and 88, thus enabling charge carriers generated in the photoelectric conversion layer 84 to be temporarily accumulated. Further, the readout electrode 81A is electrically coupled to the amplifier transistor AMP or the like provided in the semiconductor substrate 30 via the through-electrodes 34 and 88.

### 4-6. Other Modification Examples

The foregoing Modification Examples 11 to 13 exemplify, in the photodetection elements 10A to 10C, the use of the photoelectric conversion section 20 of the first embodiment as the photoelectric conversion section; however, this is not limitative. The photoelectric conversion sections 20A to 20H of the foregoing Modification Examples 1 to 8, the photoelectric conversion section 60 of the second embodiment, or the photoelectric conversion sections 60A and 60B of Modification Examples 9 and 10 may be applied to the photoelectric conversion section 20 of the photodetection elements 10A to 10C. Likewise, the photoelectric conversion sections 20A to 20H of Modification Examples 1 to 8, the photoelectric conversion section 60 of the second embodiment, or the photoelectric conversion sections 60A and 60B of Modification Examples 9 and 10 may be applied to the photoelectric conversion section 80 of Modification Example 13.

### 5. Application Examples

### Application Example 1

FIG. 40 illustrates an example of an overall configuration of a photodetector (photodetector 1) including the photodetection element (e.g., photodetection element 10) illustrated in FIG. 1 or other drawings.

The photodetector 1 is, for example, a CMOS image sensor. The photodetector 1 takes in incident light (image light) from a subject via an optical lens system (unillustrated), and converts the amount of incident light formed as an image on an imaging surface into electric signals in units of pixels to output the electric signals as pixel signals. The photodetector 1 includes the pixel section 1A as an imaging area on the semiconductor substrate 30. In addition, the photodetector 1 includes, for example, the vertical drive circuit 111, the column signal processing circuit 112, the horizontal drive circuit 113, the output circuit 114, the control circuit 115, and the input/output terminal 116 in a peripheral region of this pixel section 1A.

The pixel section 1A includes, for example, the plurality of unit pixels P that is two-dimensionally arranged in matrix. The unit pixels P are provided, for example, with a pixel drive line Lread (specifically, a row selection line and a reset control line) for each of pixel rows and provided with a vertical signal line Lsig for each of pixel columns. The pixel drive line Lread transmits drive signals for reading signals from the pixels. One end of the pixel drive line Lread is coupled to an output end of the vertical drive circuit 111 corresponding to each of the rows.

The vertical drive circuit 111 is a pixel drive section that is configured by a shift register, an address decoder, and the like and drives the unit pixels P of the pixel section 1A on a row-by-row basis, for example. Signals outputted from the respective unit pixels P in the pixel rows selectively scanned by the vertical drive circuit 111 are supplied to the column signal processing circuit 112 through the respective vertical signal lines Lsig. The column signal processing circuit 112 is configured by an amplifier, a horizontal selection switch, and the like provided for each of the vertical signal lines Lsig.

The horizontal drive circuit 113 is configured by a shift register, an address decoder, and the like. The horizontal drive circuit 113 drives horizontal selection switches of the column signal processing circuit 112 in order while scanning the horizontal selection switches. The selective scanning by this horizontal drive circuit 113 causes signals of the respective pixels transmitted through the respective vertical signal lines Lsig to be outputted to a horizontal signal line 121 in order and causes the signals to be transmitted to the outside of the semiconductor substrate 30 through the horizontal signal line 121.

The output circuit 114 performs signal processing on signals sequentially supplied from the respective column signal processing circuits 112 via the horizontal signal line 121, and outputs the signals. The output circuit 114 performs, for example, only buffering in some cases, and performs black level adjustment, column variation correction, various kinds of digital signal processing, and the like in other cases.

The circuit portion including the vertical drive circuit 111, the column signal processing circuit 112, the horizontal drive circuit 113, the horizontal signal line 121, and the output circuit 114 may be formed directly on the semiconductor substrate 30, or may be provided on an external control IC. In addition, the circuit portion may be formed in another substrate coupled by a cable or the like.

The control circuit 115 receives a clock supplied from the outside of the semiconductor substrate 30, data for an instruction about an operation mode, and the like and also outputs data such as internal information on the photodetector 1. The control circuit 115 further includes a timing generator that generates various timing signals, and controls driving of the peripheral circuits including the vertical drive circuit 111, the column signal processing circuit 112, the horizontal drive circuit 113, and the like on the basis of the various timing signals generated by the timing generator.

The input/output terminal 116 exchanges signals with the outside.

### Application Example 2

In addition, the above-described photodetector 1 is applicable, for example, to various types of electronic apparatuses including an imaging system such as a digital still camera and a video camera, a mobile phone having an imaging function, or another device having an imaging function.

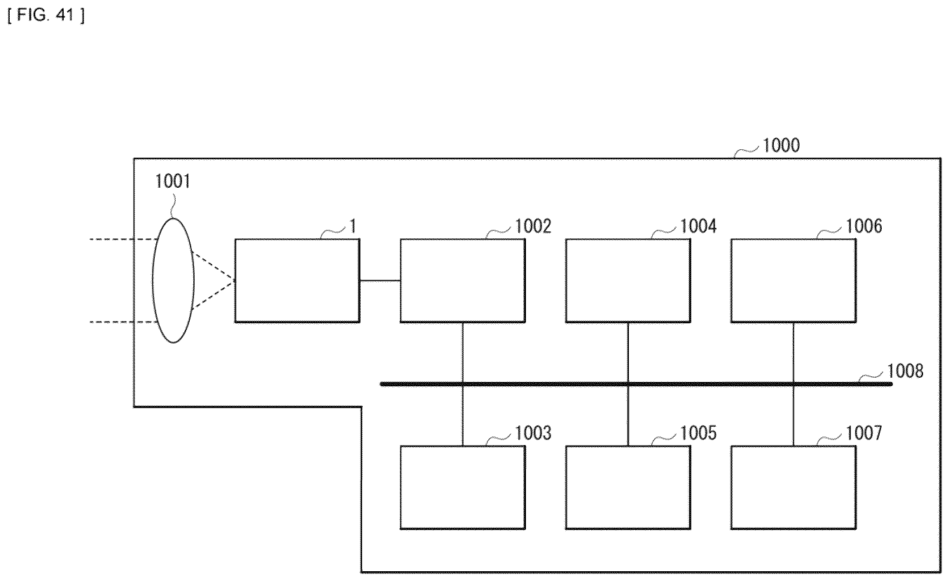

FIG. 41 is a block diagram illustrating an example of a configuration of an electronic apparatus 1000.

As illustrated in FIG. 41, the electronic apparatus 1000 includes an optical system 1001, the photodetector 1, and a DSP (Digital Signal Processor) 1002, and has a configuration in which the DSP 1002, a memory 1003, a display device 1004, a recording device 1005, an operation system 1006, and a power supply system 1007 are coupled together via a bus 1008, thus making it possible to capture a still image and a moving image.

The optical system 1001 includes one or a plurality of lenses, and takes in incident light (image light) from a subject to form an image on an imaging surface of the photodetector 1.

The above-described photodetector 1 is applied as the photodetector 1. The photodetector 1 converts the amount of incident light formed as an image on the imaging surface by the optical system 1001 into electric signals in units of pixels, and supplies the DSP 1002 with the electric signals as pixel signals.

The DSP 1002 performs various types of signal processing on the signals from the photodetector 1 to acquire an image, and causes the memory 1003 to temporarily store data on the image. The image data stored in the memory 1003 is recorded in the recording device 1005, or is supplied to the display device 1004 to display the image. In addition, the operation system 1006 receives various operations by the user, and supplies operation signals to the respective blocks of the electronic apparatus 1000. The power supply system 1007 supplies electric power required to drive the respective blocks of the electronic apparatus 1000.

### Application Example 3

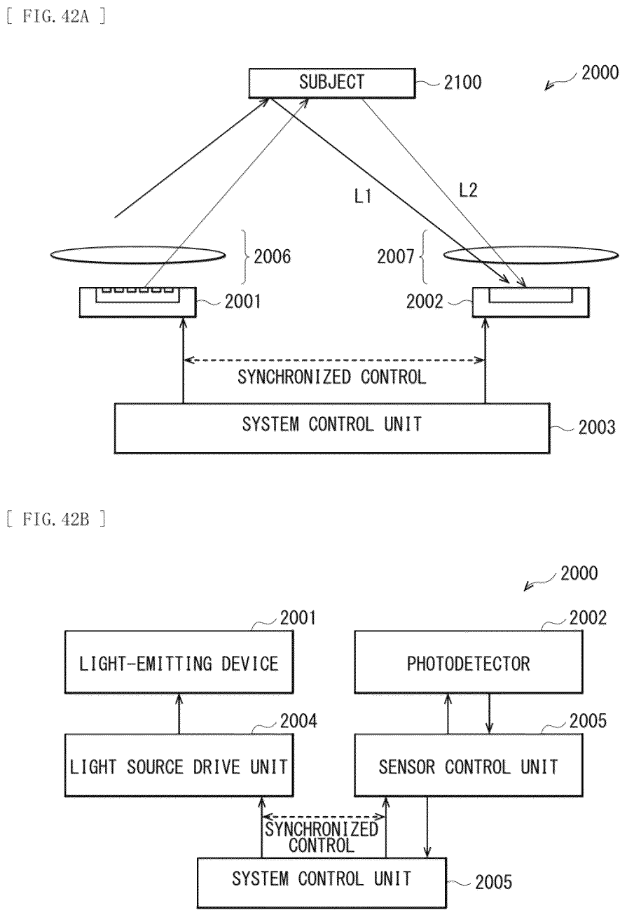

FIG. 42A schematically illustrates an example of an overall configuration of a photodetection system 2000 including the photodetector 1. FIG. 42B illustrates an example of a circuit configuration of the photodetection system 2000. The photodetection system 2000 includes a light-emitting device 2001 as a light source unit that emits infrared light L2 and a photodetector 2002 as a light-receiving unit with a photoelectric conversion element. The above-described photodetector 1 may be used as the photodetector 2002. The photodetection system 2000 may further include a system control unit 2003, a light source drive unit 2004, a sensor control unit 2005, a light source side optical system 2006, and a camera side optical system 2007.

The photodetector 2002 is able to detect light L1 and light L2. The light L1 is reflected light of ambient light from the outside reflected by a subject (measurement target) 2100 (FIG. 42A). The light L2 is light reflected by the subject 2100 after having been emitted by the light-emitting device 2001. The light L1 is, for example, visible light, and the light L2 is, for example, infrared light. The light L1 is detectable at the photoelectric conversion section in the photodetector 2002, and the light L2 is detectable at a photoelectric conversion region in the photodetector 2002. It is possible to acquire image information on the subject 2100 from the light L1 and to acquire information on a distance between the subject 2100 and the photodetection system 2000 from the light L2. For example, the photodetection system 2000 can be mounted on an electronic apparatus such as a smartphone or on a mobile body such as a car. The light-emitting device 2001 can be configured by, for example, a semiconductor laser, a surface-emitting semiconductor laser, or a vertical resonator surface-emitting laser (VCSEL). For example, an iTOF method can be employed as a method for the photodetector 2002 to detect the light L2 emitted from the light-emitting device 2001; however, this is not limitative. In the iTOF method, the photoelectric conversion section is able to measure a distance to the subject 2100 by time of flight of light (Time-of-Flight; TOF), for example. As a method for the photodetector 2002 to detect the light L2 emitted from the light-emitting device 2001, it is also possible to employ, for example, a structured light method or a stereovision method. For example, in the structured light method, light having a predetermined pattern is projected on the subject 2100, and distortion of the pattern is analyzed, thereby making it possible to measure the distance between the photodetection system 2000 and the subject 2100. In addition, in the stereovision method, for example, two or more cameras are used to acquire two or more images of the subject 2100 viewed from two or more different viewpoints, thereby making it possible to measure the distance between the photodetection system 2000 and the subject. It is to be noted that it is possible for the system control unit 2003 to synchronously control the light-emitting device 2001 and the photodetector 2002.

### 6. Practical Application Examples

### Example of Practical Application to Endoscopic Surgery System

The technology according to an embodiment of the present disclosure (present technology) is applicable to various products. For example, the technology according to an embodiment of the present disclosure may be applied to an endoscopic surgery system.

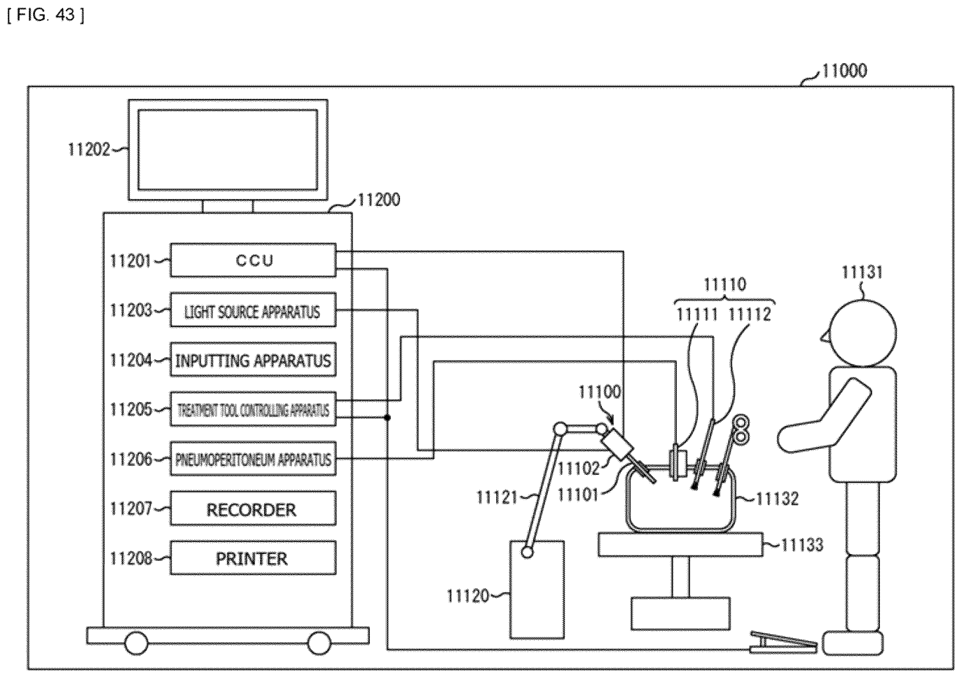

FIG. 43 is a view depicting an example of a schematic configuration of an endoscopic surgery system to which the technology according to an embodiment of the present disclosure (present technology) can be applied.

In FIG. 43, a state is illustrated in which a surgeon (medical doctor) 11131 is using an endoscopic surgery system 11000 to perform surgery for a patient 11132 on a patient bed 11133. As depicted, the endoscopic surgery system 11000 includes an endoscope 11100, other surgical tools 11110 such as a pneumoperitoneum tube 11111 and an energy device 11112, a supporting arm apparatus 11120 which supports the endoscope 11100 thereon, and a cart 11200 on which various apparatus for endoscopic surgery are mounted.

The endoscope 11100 includes a lens barrel 11101 having a region of a predetermined length from a distal end thereof to be inserted into a body cavity of the patient 11132, and a camera head 11102 connected to a proximal end of the lens barrel 11101. In the example depicted, the endoscope 11100 is depicted which includes as a rigid endoscope having the lens barrel 11101 of the hard type. However, the endoscope 11100 may otherwise be included as a flexible endoscope having the lens barrel 11101 of the flexible type.

The lens barrel 11101 has, at a distal end thereof, an opening in which an objective lens is fitted. A light source apparatus 11203 is connected to the endoscope 11100 such that light generated by the light source apparatus 11203 is introduced to a distal end of the lens barrel 11101 by a light guide extending in the inside of the lens barrel 11101 and is irradiated toward an observation target in a body cavity of the patient 11132 through the objective lens. It is to be noted that the endoscope 11100 may be a forward-viewing endoscope or may be an oblique-viewing endoscope or a side-viewing endoscope.

An optical system and an image pickup element are provided in the inside of the camera head 11102 such that reflected light (observation light) from the observation target is condensed on the image pickup element by the optical system. The observation light is photo-electrically converted by the image pickup element to generate an electric signal corresponding to the observation light, namely, an image signal corresponding to an observation image. The image signal is transmitted as RAW data to a CCU 11201.

The CCU 11201 includes a central processing unit (CPU), a graphics processing unit (GPU) or the like and integrally controls operation of the endoscope 11100 and a display apparatus 11202. Further, the CCU 11201 receives an image signal from the camera head 11102 and performs, for the image signal, various image processes for displaying an image based on the image signal such as, for example, a development process (demosaic process).

The display apparatus 11202 displays thereon an image based on an image signal, for which the image processes have been performed by the CCU 11201, under the control of the CCU 11201.

The light source apparatus 11203 includes a light source such as, for example, a light emitting diode (LED) and supplies irradiation light upon imaging of a surgical region to the endoscope 11100.

An inputting apparatus 11204 is an input interface for the endoscopic surgery system 11000. A user can perform inputting of various kinds of information or instruction inputting to the endoscopic surgery system 11000 through the inputting apparatus 11204. For example, the user would input an instruction or a like to change an image pickup condition (type of irradiation light, magnification, focal distance or the like) by the endoscope 11100.

A treatment tool controlling apparatus 11205 controls driving of the energy device 11112 for cautery or incision of a tissue, sealing of a blood vessel or the like. A pneumoperitoneum apparatus 11206 feeds gas into a body cavity of the patient 11132 through the pneumoperitoneum tube 11111 to inflate the body cavity in order to secure the field of view of the endoscope 11100 and secure the working space for the surgeon. A recorder 11207 is an apparatus capable of recording various kinds of information relating to surgery. A printer 11208 is an apparatus capable of printing various kinds of information relating to surgery in various forms such as a text, an image or a graph.

It is to be noted that the light source apparatus 11203 which supplies irradiation light when a surgical region is to be imaged to the endoscope 11100 may include a white light source which includes, for example, an LED, a laser light source or a combination of them. Where a white light source includes a combination of red, green, and blue (RGB) laser light sources, since the output intensity and the output timing can be controlled with a high degree of accuracy for each color (each wavelength), adjustment of the white balance of a picked up image can be performed by the light source apparatus 11203. Further, in this case, if laser beams from the respective RGB laser light sources are irradiated time-divisionally on an observation target and driving of the image pickup elements of the camera head 11102 are controlled in synchronism with the irradiation timings. Then images individually corresponding to the R, G and B colors can be also picked up time-divisionally. According to this method, a color image can be obtained even if color filters are not provided for the image pickup element.

Further, the light source apparatus 11203 may be controlled such that the intensity of light to be outputted is changed for each predetermined time. By controlling driving of the image pickup element of the camera head 11102 in synchronism with the timing of the change of the intensity of light to acquire images time-divisionally and synthesizing the images, an image of a high dynamic range free from underexposed blocked up shadows and overexposed highlights can be created.

Further, the light source apparatus 11203 may be configured to supply light of a predetermined wavelength band ready for special light observation. In special light observation, for example, by utilizing the wavelength dependency of absorption of light in a body tissue to irradiate light of a narrow band in comparison with irradiation light upon ordinary observation (namely, white light), narrow band observation (narrow band imaging) of imaging a predetermined tissue such as a blood vessel of a superficial portion of the mucous membrane or the like in a high contrast is performed. Alternatively, in special light observation, fluorescent observation for obtaining an image from fluorescent light generated by irradiation of excitation light may be performed. In fluorescent observation, it is possible to perform observation of fluorescent light from a body tissue by irradiating excitation light on the body tissue (autofluorescence observation) or to obtain a fluorescent light image by locally injecting a reagent such as indocyanine green (ICG) into a body tissue and irradiating excitation light corresponding to a fluorescent light wavelength of the reagent upon the body tissue. The light source apparatus 11203 can be configured to supply such narrow-band light and/or excitation light suitable for special light observation as described above.

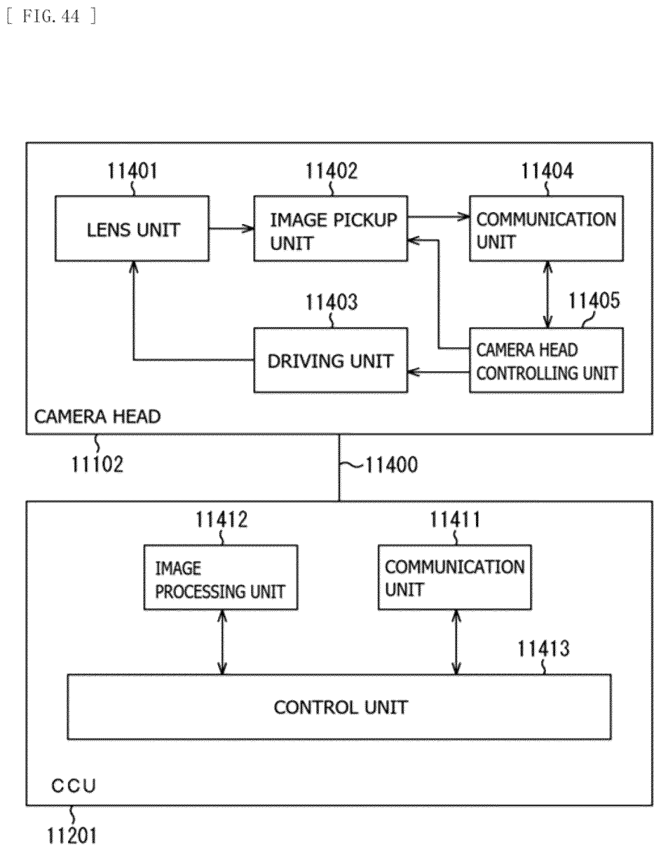

FIG. 44 is a block diagram depicting an example of a functional configuration of the camera head 11102 and the CCU 11201 depicted in FIG. 43.

The camera head 11102 includes a lens unit 11401, an image pickup unit 11402, a driving unit 11403, a communication unit 11404 and a camera head controlling unit 11405. The CCU 11201 includes a communication unit 11411, an image processing unit 11412 and a control unit 11413. The camera head 11102 and the CCU 11201 are connected for communication to each other by a transmission cable 11400.

The lens unit 11401 is an optical system, provided at a connecting location to the lens barrel 11101. Observation light taken in from a distal end of the lens barrel 11101 is guided to the camera head 11102 and introduced into the lens unit 11401. The lens unit 11401 includes a combination of a plurality of lenses including a zoom lens and a focusing lens.

The number of image pickup elements which is included by the image pickup unit 11402 may be one (single-plate type) or a plural number (multi-plate type). Where the image pickup unit 11402 is configured as that of the multi-plate type, for example, image signals corresponding to respective R, G and B are generated by the image pickup elements, and the image signals may be synthesized to obtain a color image. The image pickup unit 11402 may also be configured so as to have a pair of image pickup elements for acquiring respective image signals for the right eye and the left eye ready for three dimensional (3D) display. If 3D display is performed, then the depth of a living body tissue in a surgical region can be comprehended more accurately by the surgeon 11131. It is to be noted that, where the image pickup unit 11402 is configured as that of stereoscopic type, a plurality of systems of lens units 11401 are provided corresponding to the individual image pickup elements.

Further, the image pickup unit 11402 may not necessarily be provided on the camera head 11102. For example, the image pickup unit 11402 may be provided immediately behind the objective lens in the inside of the lens barrel 11101.

The driving unit 11403 includes an actuator and moves the zoom lens and the focusing lens of the lens unit 11401 by a predetermined distance along an optical axis under the control of the camera head controlling unit 11405. Consequently, the magnification and the focal point of a picked up image by the image pickup unit 11402 can be adjusted suitably.

The communication unit 11404 includes a communication apparatus for transmitting and receiving various kinds of information to and from the CCU 11201. The communication unit 11404 transmits an image signal acquired from the image pickup unit 11402 as RAW data to the CCU 11201 through the transmission cable 11400.

In addition, the communication unit 11404 receives a control signal for controlling driving of the camera head 11102 from the CCU 11201 and supplies the control signal to the camera head controlling unit 11405. The control signal includes information relating to image pickup conditions such as, for example, information that a frame rate of a picked up image is designated, information that an exposure value upon image picking up is designated and/or information that a magnification and a focal point of a picked up image are designated.

It is to be noted that the image pickup conditions such as the frame rate, exposure value, magnification or focal point may be designated by the user or may be set automatically by the control unit 11413 of the CCU 11201 on the basis of an acquired image signal. In the latter case, an auto exposure (AE) function, an auto focus (AF) function and an auto white balance (AWB) function are incorporated in the endoscope 11100.

The camera head controlling unit 11405 controls driving of the camera head 11102 on the basis of a control signal from the CCU 11201 received through the communication unit 11404.

The communication unit 11411 includes a communication apparatus for transmitting and receiving various kinds of information to and from the camera head 11102. The communication unit 11411 receives an image signal transmitted thereto from the camera head 11102 through the transmission cable 11400.

Further, the communication unit 11411 transmits a control signal for controlling driving of the camera head 11102 to the camera head 11102. The image signal and the control signal can be transmitted by electrical communication, optical communication or the like.

The image processing unit 11412 performs various image processes for an image signal in the form of RAW data transmitted thereto from the camera head 11102.

The control unit 11413 performs various kinds of control relating to image picking up of a surgical region or the like by the endoscope 11100 and display of a picked up image obtained by image picking up of the surgical region or the like. For example, the control unit 11413 creates a control signal for controlling driving of the camera head 11102.

Further, the control unit 11413 controls, on the basis of an image signal for which image processes have been performed by the image processing unit 11412, the display apparatus 11202 to display a picked up image in which the surgical region or the like is imaged. Thereupon, the control unit 11413 may recognize various objects in the picked up image using various image recognition technologies. For example, the control unit 11413 can recognize a surgical tool such as forceps, a particular living body region, bleeding, mist when the energy device 11112 is used and so forth by detecting the shape, color and so forth of edges of objects included in a picked up image. The control unit 11413 may cause, when it controls the display apparatus 11202 to display a picked up image, various kinds of surgery supporting information to be displayed in an overlapping manner with an image of the surgical region using a result of the recognition. Where surgery supporting information is displayed in an overlapping manner and presented to the surgeon 11131, the burden on the surgeon 11131 can be reduced and the surgeon 11131 can proceed with the surgery with certainty.

The transmission cable 11400 which connects the camera head 11102 and the CCU 11201 to each other is an electric signal cable ready for communication of an electric signal, an optical fiber ready for optical communication or a composite cable ready for both of electrical and optical communications.

Here, while, in the example depicted, communication is performed by wired communication using the transmission cable 11400, the communication between the camera head 11102 and the CCU 11201 may be performed by wireless communication.

The description has been given above of one example of the endoscopic surgery system, to which the technology according to an embodiment of the present disclosure is applicable. The technology according to an embodiment of the present disclosure is applicable to, for example, the image pickup unit 11402 of the configurations described above. Applying the technology according to an embodiment of the present disclosure to the image pickup unit 11402 makes it possible to improve detection accuracy.

It is to be noted that although the endoscopic surgery system has been described as an example here, the technology according to an embodiment of the present disclosure may also be applied to, for example, a microscopic surgery system, and the like.

### Example of Practical Application to Mobile Body

The technology according to an embodiment of the present disclosure (present technology) is applicable to various products. For example, the technology according to an embodiment of the present disclosure may be achieved in the form of an apparatus to be mounted to a mobile body of any kind. Non-limiting examples of the mobile body may include an automobile, an electric vehicle, a hybrid electric vehicle, a motorcycle, a bicycle, any personal mobility device, an airplane, an unmanned aerial vehicle (drone), a vessel, a robot, a construction machine, and an agricultural machine (tractor).

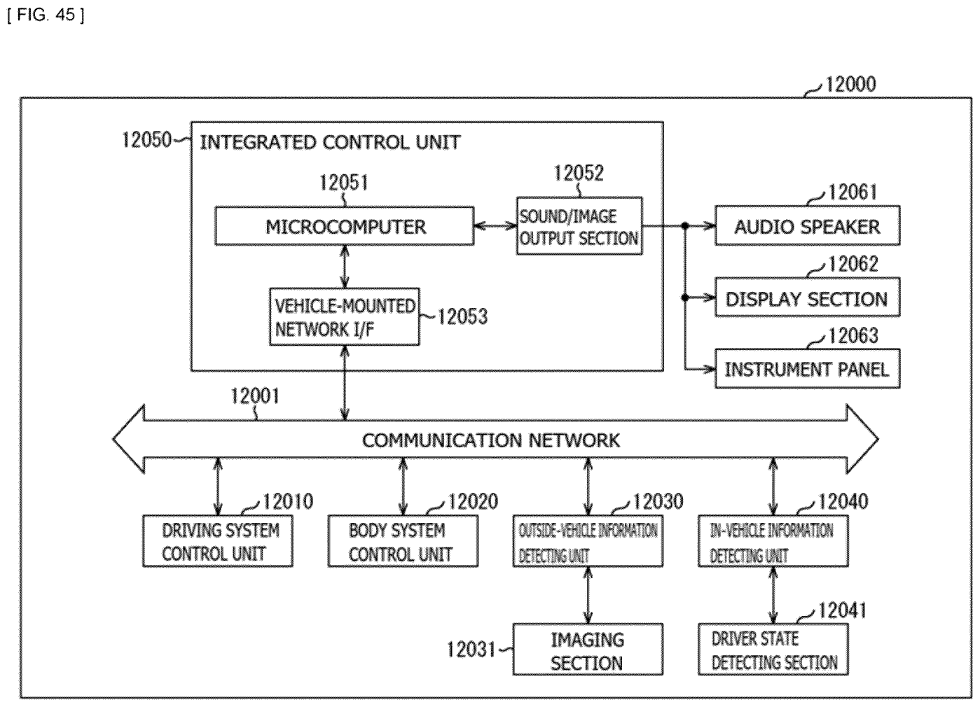

FIG. 45 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 45, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 45, an audio speaker 12061, a display section 12062, and an instrument panel 12063 are illustrated as the output device. The display section 12062 may, for example, include at least one of an on-board display and a head-up display.

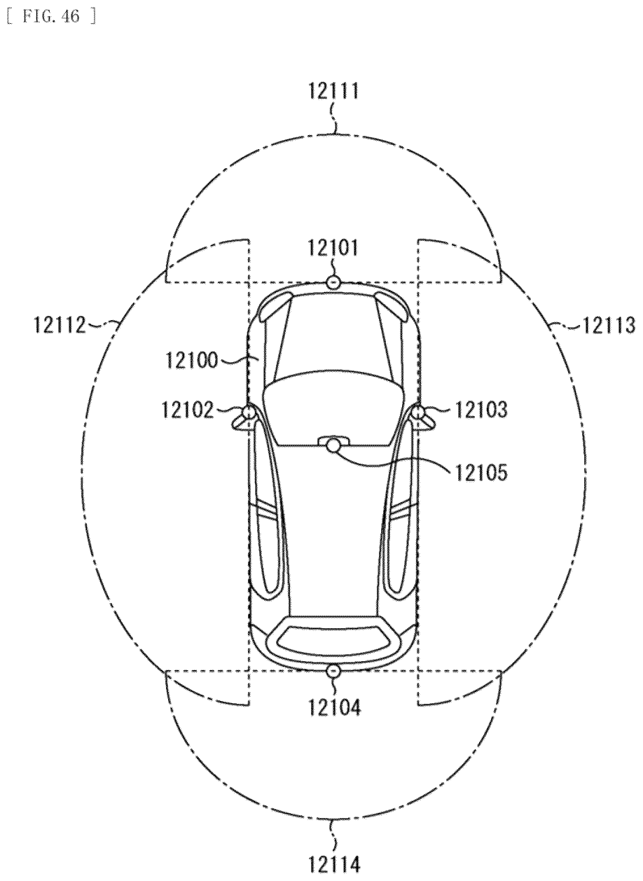

FIG. 46 is a diagram depicting an example of the installation position of the imaging section 12031.

In FIG. 46, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 46 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of photodetection elements, or may be a photodetection element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

The description has been given hereinabove of one example of the mobile body control system, to which the technology according to an embodiment of the present disclosure may be applied. The technology according to an embodiment of the present disclosure may be applied to the imaging section 12031 among components of the configuration described above. Specifically, the photodetector (e.g., the photodetector 1) according to the foregoing embodiments and the like is applicable to the imaging section 12031. Applying the technology according to an embodiment of the present disclosure to the imaging section 12031 allows for a high-definition captured image with less noise, thus making it possible to perform highly accurate control utilizing the captured image in the mobile body control system.

Description has been given hereinabove by referring to the first and second embodiments and Modification Examples 1 to 13 as well as the application examples and the practical application examples; however, the content of the present disclosure is not limited to the foregoing embodiments and the like, and may be modified in a wide variety of ways. For example, in the foregoing first embodiment, the photodetection element has a configuration in which the photoelectric conversion section 20 that detects green light and the photoelectric conversion regions 32B and 32R that detect, respectively, blue light and red light are stacked. However, the content of the present disclosure is not limited to such a structure. For example, red light or blue light may be detected in the photoelectric conversion section, or green light may be detected in the photoelectric conversion region.

Further, the numbers of the photoelectric conversion section and the photoelectric conversion region, and the ratio therebetween are not limitative. Two or more photoelectric conversion sections may be provided, or only a photoelectric conversion section may be used to obtain color signals of a plurality of colors.

Further, the foregoing embodiments and the like exemplify, as the plurality of electrodes constituting the lower electrode 21, the four electrodes of the readout electrode 21A, the accumulation electrode 21B, the pixel separation electrode 21C, and the transfer electrode 21D. However, in addition thereto, an electrode such as a discharge electrode may be provided.

It is to be noted that the effects described herein are merely exemplary and are not limitative, and may further include other effects.

It is to be noted that the present technology may also have the following configurations. According to the present technology of the following configurations, it is possible to prevent the formation of a parasitic transistor between a first electrode and an oxide semiconductor layer. Alternatively, it is possible to increase a potential margin for a parasitic transistor part formed between the first electrode and the oxide semiconductor layer outside an opening. It is therefore possible to improve reliability.
(1)

A photoelectric conversion element including:
an electrode layer including a first electrode and a second electrode disposed side by side with each other;
a third electrode disposed to be opposed to the first electrode and the second electrode;
a photoelectric conversion layer provided between the electrode layer and the third electrode;
an oxide semiconductor layer provided between the electrode layer and the photoelectric conversion layer; and
a first insulating layer provided between the electrode layer and the oxide semiconductor layer, in which
the first insulating layer has an opening in which an entire top surface of the first electrode is in contact with the oxide semiconductor layer without the first insulating layer being interposed therebetween.
(2)

The photoelectric conversion element according to (1), in which a bottom of the opening has an area that is equal to or larger than an area of the top surface of the first electrode.
(3)

The photoelectric conversion element according to (1) or (2), in which an end of the bottom of the opening coincides with an end of the top surface of the first electrode.
(4)

The photoelectric conversion element according to (1) or (2), in which
an end of the bottom of the opening is provided outside an end of the top surface of the first electrode, and
a minimum distance between the end of the bottom of the opening and the end of the top surface of the first electrode is smaller than a minimum distance between the end of the opening and an end of a top surface of the second electrode.
(5)

The photoelectric conversion element according to any one of (1) to (4), in which the oxide semiconductor layer is further in contact with a side surface of the first electrode.
(6)

The photoelectric conversion element according to any one of (1) to (5), in which a bottom surface of the first electrode and the bottom of the opening are formed on substantially a same plane.
(7)

The photoelectric conversion element according to any one of (1) to (6), in which the electrode layer is provided on a second insulating layer having an etching rate different from the first insulating layer.
(8)

The photoelectric conversion element according to any one of (1) to (7), in which the second insulating layer having an etching rate different from the first insulating layer is provided between the first electrode and the second electrode.
(9)

The photoelectric conversion element according to any one of (1) to (8), in which side surfaces of the first electrode and the second electrode are each provided with a sidewall having an etching rate different from the first insulating layer.
(10)

The photoelectric conversion element according to any one of (1) to (9), in which the opening has a planar shape that is substantially same as a planar shape of the first electrode.
(11)

The photoelectric conversion element according to any one of (1) to (9), in which the opening has a planar shape that is different from a planar shape of the first electrode.
(12)

The photoelectric conversion element according to any one of (1) to (11), in which
the first electrode is thicker than the second electrode, and
the top surface of the first electrode forms a same plane as a top surface of the oxide semiconductor layer.
(13)

The photoelectric conversion element according to any one of (1) to (11), in which the first electrode includes a first layer and a second layer, the first layer having a thickness same as the second electrode, the second layer being stacked on the first layer and extending from the bottom of the opening to a side surface of the opening and a top surface of the first insulating layer.
(14)

The photoelectric conversion element according to any one of (1) to (13), further including an inorganic buffer layer including a metal oxide between the photoelectric conversion layer and the oxide semiconductor layer.
(15)

The photoelectric conversion element according to any one of (1) to (14), further including a fourth electrode provided between the first electrode and the second electrode.
(16)

A photoelectric conversion element including:
an electrode layer including a first electrode and a second electrode disposed side by side with each other;
a third electrode disposed to be opposed to the first electrode and the second electrode;
a photoelectric conversion layer provided between the electrode layer and the third electrode;
an oxide semiconductor layer provided between the electrode layer and the photoelectric conversion layer;
a first insulating layer provided between the electrode layer and the oxide semiconductor layer, the first insulating layer having, above the first electrode, an opening that allows for electrical coupling between the first electrode and the oxide semiconductor layer; and
a work function adjustment layer provided on the first electrode.
(17)

The photoelectric conversion element according to (16), in which the work function adjustment layer includes an oxide material including at least one of silicon, germanium, tantalum, titanium, vanadium, niobium, tantalum, zirconium, hafnium, scandium, yttrium, strontium, or lanthanum.
(18)

The photoelectric conversion element according to (16) or (17), in which the work function adjustment layer coats a top surface and a side surface of the first electrode.
(19)

The photoelectric conversion element according to any one of (16) to (18), in which the work function adjustment layer has a thickness of 1 atomic layer or more and less than 2 nm.
(20)

The photoelectric conversion element according to any one of (16) to (19), in which, in the work function adjustment layer, the first electrode is exposed at a bottom of the opening.
(21)

A photodetector including a plurality of pixels each including one or a plurality of photoelectric conversion elements, the photoelectric conversion element including
an electrode layer including a first electrode and a second electrode disposed side by side with each other,
a third electrode disposed to be opposed to the first electrode and the second electrode,
a photoelectric conversion layer provided between the electrode layer and the third electrode,
an oxide semiconductor layer provided between the electrode layer and the photoelectric conversion layer, and
a first insulating layer provided between the electrode layer and the oxide semiconductor layer, in which
the first insulating layer has an opening in which an entire top surface of the first electrode is in contact with the oxide semiconductor layer without the first insulating layer being interposed therebetween.
(22)

A photodetector including a plurality of pixels each including one or a plurality of photoelectric conversion elements, the photoelectric conversion element including
an electrode layer including a first electrode and a second electrode disposed side by side with each other,
a third electrode disposed to be opposed to the first electrode and the second electrode,
a photoelectric conversion layer provided between the electrode layer and the third electrode,
an oxide semiconductor layer provided between the electrode layer and the photoelectric conversion layer,
a first insulating layer provided between the electrode layer and the oxide semiconductor layer, the first insulating layer having, above the first electrode, an opening that allows for electrical coupling between the first electrode and the oxide semiconductor layer, and
a work function adjustment layer provided on the first electrode.

The present application claims the benefit of Japanese Priority Patent Application JP2022-158948 filed with the Japan Patent Office on Sep. 30, 2022, the entire contents of which are incorporated herein by reference.

It should be understood by those skilled in the art that various modifications, combinations, sub-combinations, and alterations may occur depending on design requirements and other factors insofar as they are within the scope of the appended claims or the equivalents thereof.

1. A photoelectric conversion element comprising:
an electrode layer including a first electrode and a second electrode disposed side by side with each other;
a third electrode disposed to be opposed to the first electrode and the second electrode;
a photoelectric conversion layer provided between the electrode layer and the third electrode;
an oxide semiconductor layer provided between the electrode layer and the photoelectric conversion layer; and
a first insulating layer provided between the electrode layer and the oxide semiconductor layer, wherein
the first insulating layer has an opening in which an entire top surface of the first electrode is in contact with the oxide semiconductor layer without the first insulating layer being interposed therebetween.

2. The photoelectric conversion element according to claim 1, wherein a bottom of the opening has an area that is equal to or larger than an area of the top surface of the first electrode.

3. The photoelectric conversion element according to claim 1, wherein an end of a bottom of the opening coincides with an end of the top surface of the first electrode.

4. The photoelectric conversion element according to claim 1, wherein
an end of a bottom of the opening is provided outside an end of the top surface of the first electrode, and
a minimum distance between the end of the bottom of the opening and the end of the top surface of the first electrode is smaller than a minimum distance between the end of the opening and an end of a top surface of the second electrode.

5. The photoelectric conversion element according to claim 1, wherein the oxide semiconductor layer is further in contact with a side surface of the first electrode.

6. The photoelectric conversion element according to claim 1, wherein a bottom surface of the first electrode and a bottom of the opening are formed on substantially a same plane.

7. The photoelectric conversion element according to claim 1, wherein the electrode layer is provided on a second insulating layer having an etching rate different from the first insulating layer.

8. The photoelectric conversion element according to claim 1, wherein a second insulating layer having an etching rate different from the first insulating layer is provided between the first electrode and the second electrode.

9. The photoelectric conversion element according to claim 1, wherein side surfaces of the first electrode and the second electrode are each provided with a sidewall having an etching rate different from the first insulating layer.

10. The photoelectric conversion element according to claim 1, wherein the opening has a planar shape that is substantially same as a planar shape of the first electrode.

11. The photoelectric conversion element according to claim 1, wherein the opening has a planar shape that is different from a planar shape of the first electrode.

12. The photoelectric conversion element according to claim 1, wherein
the first electrode is thicker than the second electrode, and
the top surface of the first electrode forms a same plane as a top surface of the oxide semiconductor layer.

13. The photoelectric conversion element according to claim 1, wherein the first electrode includes a first layer and a second layer, the first layer having a thickness same as the second electrode, the second layer being stacked on the first layer and extending from a bottom of the opening to a side surface of the opening and a top surface of the first insulating layer.

14. The photoelectric conversion element according to claim 1, further comprising an inorganic buffer layer including a metal oxide between the photoelectric conversion layer and the oxide semiconductor layer.

15. The photoelectric conversion element according to claim 1, further comprising a fourth electrode provided between the first electrode and the second electrode.

16. A photoelectric conversion element comprising:
an electrode layer including a first electrode and a second electrode disposed side by side with each other;
a third electrode disposed to be opposed to the first electrode and the second electrode;
a photoelectric conversion layer provided between the electrode layer and the third electrode;
an oxide semiconductor layer provided between the electrode layer and the photoelectric conversion layer;
a first insulating layer provided between the electrode layer and the oxide semiconductor layer, the first insulating layer having, above the first electrode, an opening that allows for electrical coupling between the first electrode and the oxide semiconductor layer; and
a work function adjustment layer provided on the first electrode.

17. The photoelectric conversion element according to claim 16, wherein the work function adjustment layer includes an oxide material including at least one of silicon, germanium, tantalum, titanium, vanadium, niobium, tantalum, zirconium, hafnium, scandium, yttrium, strontium, or lanthanum.

18. The photoelectric conversion element according to claim 16, wherein the work function adjustment layer coats a top surface and a side surface of the first electrode.

19. The photoelectric conversion element according to claim 16, wherein the work function adjustment layer has a thickness of 1 atomic layer or more and less than 2 nm.

20. The photoelectric conversion element according to claim 16, wherein, in the work function adjustment layer, the first electrode is exposed at a bottom of the opening.

21. A photodetector comprising a plurality of pixels each including one or a plurality of photoelectric conversion elements, the photoelectric conversion element including
an electrode layer including a first electrode and a second electrode disposed side by side with each other,
a third electrode disposed to be opposed to the first electrode and the second electrode,
a photoelectric conversion layer provided between the electrode layer and the third electrode,
an oxide semiconductor layer provided between the electrode layer and the photoelectric conversion layer, and
a first insulating layer provided between the electrode layer and the oxide semiconductor layer, wherein
the first insulating layer has an opening in which an entire top surface of the first electrode is in contact with the oxide semiconductor layer without the first insulating layer being interposed therebetween.

22. A photodetector comprising a plurality of pixels each including one or a plurality of photoelectric conversion elements, the photoelectric conversion element including
an electrode layer including a first electrode and a second electrode disposed side by side with each other,
a third electrode disposed to be opposed to the first electrode and the second electrode,
a photoelectric conversion layer provided between the electrode layer and the third electrode,
an oxide semiconductor layer provided between the electrode layer and the photoelectric conversion layer,
a first insulating layer provided between the electrode layer and the oxide semiconductor layer, the first insulating layer having, above the first electrode, an opening that allows for electrical coupling between the first electrode and the oxide semiconductor layer, and
a work function adjustment layer provided on the first electrode.
